(19) United States
(12) Patent Application Publication
(10) Pub. No.: US 2026/0049416 A1
(43) Pub. Date: Feb. 19, 2026

(54) HIGH-ENTROPY HALIDE PEROVSKITE SINGLE CRYSTALS STABILIZED BY MILD CHEMISTRY

(71) Applicant: The Regents of the University of California, Oakland, CA (US)

(72) Inventors: Peidong Yang, Kensington, CA (US); Maria C. Folgueras, Phoenixville, PA (US); Yuxin Jiang, Albany, CA (US)

(21) Appl. No.: 19/299,151

(22) Filed: Aug. 13, 2025

Related U.S. Application Data
(60) Provisional application No. 63/683,518, filed on Aug. 15, 2024.

(51) Int. Cl. C30B 29/12; C01B 19/00; C09K 11/88; C30B 7/14

(52) U.S. Cl. CPC C30B 29/12; C01B 19/002; C09K 11/88; C30B 7/14; C01P 2002/50; C01P 2002/72; C01P 2002/74; C01P 2002/77; C01P 2002/84; C01P 2004/03; C01P 2006/60

(57) ABSTRACT

High-entropy materials according to the formula Cs₂{M}Cl₆ are provided. {M} is a combination of at least five metal cations each occupying the M-site of the high-entropy material as a random alloy, e.g., in near-equimolar ratios. The high-entropy materials provided herein includes five or six-element halide perovskite semiconductor single crystals of the Cs₂{SnTeReOsIrPt}₁Cl₆ family and the Cs₂{ZrSnTeHfRePt}₁Cl₆ family. Also provided are methods of generating a high-entropy material, e.g., metal halide perovskite high-entropy semiconductor single crystals, by contacting Cs⁺ molecules with at least five different [MCl₆]²⁻ molecules in a solvent, forming via a self-assembly process the high-entropy material according to the formula Cs₂{M}Cl₆. The method is conducted at milder temperature (e.g., at a temperature of 100° C. or lower) relative to traditional methods of high-entropy material synthesis which typically requires procedures of over 1,000° C.

### CROSS-REFERENCE TO RELATED APPLICATIONS

This application claims priority to U.S. Provisional Application No. 63/683,518, filed on Aug. 15, 2024, the content of which is incorporated herein by reference in its entirety.

### STATEMENT OF GOVERNMENT SUPPORT

This invention was made with government support under Contract No. DE-AC02-05CH11231 awarded by the U.S. Department of Energy. The government has certain rights in this invention.

### TECHNICAL FIELD

This disclosure relates generally to high-entropy alloys and high-entropy semiconductors.

### BACKGROUND

High-entropy alloys (HEAs) are studied across a range of material classes, particularly high-entropy metals (HEMs) and high-entropy ceramics (HECs), for their exceptional functional properties, leaving much to be explored in the field of high-entropy semiconductors (HESs). Although high-entropy materials are excellent candidates for a range of functional materials, formation of single-phase, crystalline solid solutions traditionally requires extreme temperature synthetic procedures of over 1,000° C. and complex processing techniques such as hot rolling. The extreme synthetic requirements for high-entropy materials is often incompatible with the stability of other materials in a device architecture. Further, the extensive energy input makes it challenging to scale up the production of high-entropy materials for large-scale applications. In addition, even under the extreme synthetic conditions, formation of a high-entropy materials from any combination of multiple components is not guaranteed.

### BRIEF SUMMARY

In view of the foregoing, there is a need for systems for the synthesis of high-entropy materials that involve milder and simpler requirements and processes. This disclosure is directed generally to systems, compositions, and methods to address these shortcomings of the art and provide other additional or alternative advantages.

Provided herein are room-temperature-solution (20° C.) and low-temperature-solution (80° C.) synthesis procedures for a new class of metal halide perovskite high-entropy semiconductor (HES) single crystals. The soft, easily reconfigurable lattices and facile, low-to-mild temperature-solution processability of halide-based perovskites and the design of crystal structures with ionic bonding networks and low cohesive energies allow the mild synthesis procedures for high-entropy materials.

Due to the soft, ionic lattice nature of metal halide perovskites, these HES single crystals are designed on the cubic Cs₂MCl₆ (M=Zr⁴⁺, Sn⁴⁺, Te⁴⁺, Hf⁴⁺, Re⁴⁺, Os⁴⁺, Ir⁴⁺ or Pt⁴⁺) vacancy-ordered double perovskite structure from the self-assembly of stabilized complexes in multi-element inks, namely free Cs⁺ cations and five or six different isolated [MCl₆]²⁻ anionic octahedral molecules well-mixed in strong hydrochloric acid. The resulting single-phase single crystals include two HES families of five and six elements occupying the M-site as a random alloy in near equimolar ratios, with the overall Cs₂MCl₆ crystal structure and stoichiometry maintained. The incorporation of various [MCl₆]²⁻ octahedral molecular orbitals disordered across high-entropy five- and six-element Cs₂MCl₆ single crystals produces complex vibrational and electronic structures with energy transfer interactions between the confined exciton states of the five or six different isolated octahedral molecules.

In one aspect of the present disclosure, a high-entropy material according to the formula Cs₂{M}Cl₆ is provided. {M} is a combination of at least five metal cations each occupying the M-site of the high-entropy material as a random alloy.

In some embodiments, the at least five metal cations occupy the M-site in near-equimolar ratios.

In some embodiments, the high-entropy material comprises a single phase single crystal.

In some embodiments, the at least five metal cations are tetravalent metal cations selected from the group consisting of Zr⁴⁺, Sn⁴⁺, Te⁴⁺, Hf⁴⁺, Re⁴⁺, Os⁴⁺, Ir⁴⁺ and Pt⁴⁺.

In some embodiments, the M comprises Sn⁴⁺, Te⁴⁺, Re⁴⁺, Ir⁴⁺ and Pt⁴⁺. In some embodiments, the high-entropy material has the formula: Cs₂{SnTeReOsIrPt}₁Cl₆ or Cs₂{SnTeReOsIrPt}₁Cl₆. In some embodiments, Sn, Te, Re, Os, Ir, and Pt in Cs₂{SnTeReOsIrPt}₁Cl₆, or Sn, Te, Re, Os, Ir, and Pt in Cs₂{SnTeReOsIrPt}₁Cl₆ are in near equimolar ratios. In some embodiments, the high-entropy material is according to the formula: Cs₂Sn_{0.198}Te_{0.218}Re_{0.230}Ir_{0.117}Pt_{0.237}Cl₆ or Cs₂Sn_{0.208}Te_{0.181}Re_{0.166}Os_{0.186}Ir_{0.114}Pt_{0.146}Cl₆.

In some embodiments, the M comprises Zr⁴⁺, Sn⁴⁺, Te⁴⁺, Hf⁴⁺, and Pt⁴⁺. In some embodiments, the high-entropy material has the formula: Cs₂{ZrSnTeHfPt}₁Cl₆ or Cs₂{ZrSnTeHfRePt}₁Cl₆. In some embodiments, the high-entropy material is according to the formula: Cs₂Zr_{0.266}Sn_{0.147}Te_{0.208}Hf_{0.159}Pt_{0.220}Cl₆ or Cs₂Zr_{0.237}Sn_{0.125}Te_{0.183}Hf_{0.129}Re_{0.142}Pt_{0.185}Cl₆.

In one aspect of the present disclosure, provided is a product comprising the high-entropy material provided herein. In some embodiments, the product is a processable semiconductor ink, a semiconductor, an optoelectronic device, e.g., an light-emitting diode (LED) or a display, or an electronic device, e.g., a computer chip.

In one aspect of the present disclosure, a method of generating a high-entropy material is provided. The method includes contacting Cs⁺ molecules with at least five different [MCl₆]²⁻ molecules in a solvent, forming via a self-assembly process a high-entropy material according to the formula Cs₂{M}Cl₆. The at least five different [MCl₆]²⁻ molecules each comprise a different metal cation M. {M} is a combination of the different metal cations each occupying the M-site of the high-entropy material as a random alloy. The method is conducted at a temperature of 100° C. or less (a temperature lower than 100° C.).

In some embodiments, at least five metal cations occupy the M-site in near-equimolar ratios.

In some embodiments, the method includes dissolving at least five different Cs₂MCl₆ powders in the solvent containing chloride, and the at least five different Cs₂MCl₆ powders each contain a different metal cation M.

In some embodiments, the solvent comprises 12 M HCl.

In some embodiments, the method includes dissolving the at least five different Cs₂MCl₆ molecules in the solvent at 100° C. with stirring, forming a solution, and letting the solution sit at 80° C. or lower, forming the high-entropy material. In some embodiments, the method includes dissolving the at least five different Cs₂MCl₆ molecules in the solvent at room temperature with stirring, forming a solution, and letting the solution sit at room temperature, forming the high-entropy material.

In some embodiments, the method includes forming single phase, single crystals as the high-entropy material.

In some embodiments, the at least five different [MCl₆]²⁻ molecules are selected from the group consisting of [ZrCl₆]²⁻, [SnCl₆]²⁻, [TeCl₆]²⁻, [HfCl₆]²⁻, [ReCl₆]²⁻, [OsCl₆]²⁻, [IrCl₆]²⁻, and [PtCl₆]²⁻.

In some embodiments, the at least five different Cs₂MCl₆ powders contain (i) Cs₂SnCl₆, Cs₂TeCl₆, Cs₂ReCl₆, Cs₂IrCl₆, and Cs₂PtCl₆ powders, (ii) Cs₂SnCl₆, Cs₂TeCl₆, Cs₂ReCl₆, Cs₂OsCl₆, Cs₂IrCl₆, and Cs₂PtCl₆ powders, (iii) Cs₂ZrCl₆, Cs₂SnCl₆, Cs₂TeCl₆, Cs₂HfCl₆, and Cs₂PtCl₆ powders, or (iv) Cs₂ZrCl₆, Cs₂SnCl₆, Cs₂TeCl₆, Cs₂HfCl₆, Cs₂ReCl₆ and Cs₂PtCl₆ powders.

In some embodiments, the method includes forming the high-entropy material according to the formula Cs₂{SnTeReOsIrPt}₁Cl₆, Cs₂{SnTeReOsIrPt}₁Cl₆, Cs₂{ZrSnTeHfPt}₁Cl₆, or Cs₂{ZrSnTeHfRePt}₁Cl₆.

In one aspect of the present disclosure, provided is a high-entropy material generated by the method provided herein.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1A depicts schematic representation of the room- and low-temperature-driven self-assembly processes in solution from multi-element inks to high-entropy five- or six-element Cs₂MX₆ single crystals. The use of 12 M HCl as the solvent for multi-element inks was a specific design choice, because an excess chloride environment promotes the formation of six coordinated [MCl₆]²⁻ octahedral molecules in solution. FIG. 1B depicts optical microscope images of high-entropy five-element Cs₂{SnTeReIrPt}₁Cl₆, six-element Cs₂{SnTeReOsIrPt}₁Cl₆, five-element Cs₂{ZrSnTeHfPt}₁Cl₆ and six-element Cs₂{ZrSnTeHfRePt}₁Cl₆ single crystals.

FIG. 2A depicts powder X-ray diffraction (PXRD) patterns of five-element Cs₂{SnTeReIrPt}₁Cl₆ and six-element Cs₂{SnTeReOsIrPt}₁Cl₆ single crystals, showing that the four high-entropy compositions adopt a single-phase, FCC crystal structure. FIG. 2B depicts fine scans over the FCC (111) reflection of five-element Cs₂{SnTeReIrPt}₁Cl₆ and six-element Cs₂{SnTeReOsIrPt}₁Cl₆ single crystals. FIG. 2C depicts fine scans over the FCC (220) reflection of five-element Cs₂{SnTeReIrPt}₁Cl₆ and six-element Cs₂{SnTeReOsIrPt}₁Cl₆ single crystals. FIG. 2D depicts PXRD patterns of five-element Cs₂{ZrSnTeHfPt}₁Cl₆ and six-element Cs₂{ZrSnTeHfRePt}₁Cl₆ single crystals, showing that the four high-entropy compositions adopt a single-phase, FCC crystal structure. FIG. 2E depicts fine scans over the FCC (111) reflection of five-element Cs₂{ZrSnTeHfPt}₁Cl₆ and six-element Cs₂{ZrSnTeHfRePt}₁Cl₆ single crystals. FIG. 2F depicts fine scans over the FCC (220) reflection of five-element Cs₂{ZrSnTeHfPt}₁Cl₆ and six-element Cs₂{ZrSnTeHfRePt}₁Cl₆ single crystals. FIGS. 2B, 2C, 2E, and 2F show no peak splitting and a good fit to a single Lorentzian curve (black-dashed line).

FIGS. 3A and 3B depict single crystal X-ray diffraction (SCXRD)-determined FCC unit cells of the high-entropy 5-element SnTeReIrPt single crystal or the high-entropy 5-element ZrSnTeHfPt single crystal. FIGS. 3C and 3D depict SCXRD-determined FCC unit cells of the high-entropy 6-element SnTeReOsIrPt single crystal or the high-entropy 6-element ZrSnTeHfRePt single crystal. FIGS. 3A and 3C show the complete unit cells, and FIGS. 3B and 3D show the M-sites of the unit cells in order to better visualize the 5- or 6-element occupancy, respectively.

FIG. 4 depicts scanning electron microscopy (SEM)/energy-dispersive X-ray spectroscopy (EDX) mapping of a six-element SnTeReOsIrPt single-crystal confirming the incorporation and homogeneous distribution of all six M-site elements across a single-domain. All scale bars are 20 m.

FIGS. 5A-5D depict raw X-ray fluorescence spectra collected on a 6-element SnTeReOsIrPt single crystal as part of multiwavelength anomalous diffraction (MAD) experiments at the Re L₃-edge (FIG. 5A), the Os L₃-edge (FIG. 5B), the Ir L₃-edge (FIG. 5C), and the Pt L₃-edge (FIG. 5D).

FIGS. 6A-6G depict highly resolved structural determination of the absolute configuration of M-site metal centers in high-entropy perovskite single crystals. FIG. 6A depicts comparison of theoretically and experimentally derived real (f′) and imaginary (f″) components of the anomalous scattering factor near the Re L₃, Os L₃, Ir L₃ and Pt L₃ edges in a six-element SnTeReOsIrPt single-crystal. Edge positions of real and imaginary components align quite well between theory and experiment. Slight deviations in edge position and more significant deviations in edge and post-edge shape between theory and experiment arise from the experimental fluorescence spectra containing information about the oxidation state and coordination environment of the element being probed. FIGS. 6B-6E depict 0kl plane diffraction pattern precession images: Re L₃ edge (FIG. 6B; E=10,533 eV), Os L₃ edge (FIG. 6C; E=10,869 eV), Ir L₃ edge (FIG. 6D; E=11,212 eV) and Pt L₃ edge (FIG. 6E; E=11,562 eV) of a six-element SnTeReOsIrPt single-crystal. FIG. 6F depicts more highly resolved structural determination of a six-element SnTeReOsIrPt single-crystal confirming that it perfectly assumes a FCC lattice, with the [SnCl₆]²⁻, [TeCl₆]²⁻, [ReCl₆]²⁻, [OsCl₆]²⁻, [IrCl₆]²⁻ and [PtCl₆]²⁻ octahedra depicted as FIG. 6G all incorporated and completely disordered in the unit cell and across the single crystal.

FIG. 7A depicts SEM images of a six-element ZrSnTeHfRePt single crystal using secondary electrons (left panels) and backscattered electrons (right panels). Top panels depict view of the entire single-crystal. Bottom panels depict zoomed-in view of the single crystal in the region indicated in the top images by the white-dashed box. FIG. 7B depicts SEM images of a 6-element SnTeReOsIrPt single crystal using secondary electrons (left panels) and backscattered electrons (right panels). Top panels depict view of the entire single crystal. Bottom panels depict a zoomed-in view of the single crystal in the region indicated in the top images with the white-dashed box. In FIGS. 7A and 7B, the right backscattered electron images show no atomic number contrast variations along the entire facet of the crystal, highlighting that each single crystal is a disordered system with no micrograin structure formation.

FIG. 7C depicts a six-element SnTeReOsIrPt single-crystal analyzed via electron backscattered diffraction (EBSD), with the region measured specifically indicated by the black-dashed box on the exposed crystal facet. FIG. 7D depicts inverse pole figure (IPF) of the region measured on the crystal facet, showing that the entire region (by blue coloring throughout) possesses a single orientation of the FCC (111) close-packed plane (as evidenced by IPF color key in FIG. 7C. FIG. 7E depicts IPF contour confirming that the region measured on the crystal facet possesses an orientation corresponding to the FCC (111) close-packed plane, which is consistent with the triangular geometry of the exposed facet. FIG. 7F depicts EBSD phase map of the region measured on the crystal facet, showing that the entire region possesses a single lattice parameter and thus corresponds to a single-crystal phase. The Cs₂TeCl₆ phase (colored red, as shown in the phase color key in FIG. 7C) is arbitrarily assigned for the purpose of confirming single-phase formation as opposed to micrograin formation of potentially different phases.

FIG. 8A depicts a UV-visible absorption spectrum and photoluminescence (PL) spectrum of five-element ZrSnTeHfPt single crystals. FIG. 8B depicts UV-visible absorption spectrum of the 5-element ZrSnTeHfPt single crystals (top panel) as compared to that of the constituent 1-element Cs₂ZrCl₆, Cs₂SnCl₆, Cs₂TeCl₆, Cs₂HfCl₆, and Cs₂PtCl₆ single crystals (bottom panel). Select 1-element absorption spectra appear in each segmented wavelength range (bottom panel), representing the specific octahedral molecules that have dominant electronic contributions to the corresponding wavelength segment of the absorption spectrum for the HES composition (top panel).

FIG. 8C depicts a photograph of bright gold emission from five-element ZrSnTeHfPt single crystals with excitation from a 250 nm light-emitting diode (LED). FIG. 8D depicts a photoluminescence (PL) image of the ‘Cal Golden Bear’ emission from five-element ZrSnTeHfPt single crystals under UV lamp excitation (λex=254 nm). The crystals were formed into the bear mascot shape using a shadow mask.

FIG. 8E depicts chromaticity of the emission from five-element ZrSnTeHfPt single crystals (λex=250 nm) on a Commission Internationale de l'Eclairage (CIE) diagram, located at coordinates (0.49, 0.49).

FIG. 9 depicts PL spectrum of the 5-element ZrSnTeHfPt single crystals as compared to that of the constituent 1-element Cs₂TeCl₆ and Cs₂PtCl₆ single crystals (lex=250 nm). All spectra are self-normalized, and the spectrum of the Cs₂PtCl₆ single crystals is further scaled by a factor of 1.3 to aid in visualizing its contribution to the spectrum of the 5-element ZrSnTeHfPt single crystals.

FIG. 10A depicts photoluminescence excitation (PLE) map and FIG. 10B depicts PLE line spectrum (monitored at the peak emission wavelength of 580 nm) of the 5-element ZrSnTeHfPt single crystals. The PLE results prove energy transfer behavior in these crystals by showing that the excited state origin of the gold emission band is from [ZrCl₆]²⁻, [HfCl₆]²⁻, and/or [TeCl₆]²⁻ octahedral molecules depending on the excitation wavelength. Features corresponding to these 3 octahedral molecules are highlighted in FIG. 10B.

FIG. 11A depicts PLE map and FIG. 11B depicts PLE line spectrum (monitored at the peak emission wavelength of 450 nm) of the 1-element Cs₂ZrCl₆ single crystals.

FIG. 12A depict PLE map and FIG. 12B depicts line spectrum (monitored at the peak emission wavelength of 447 nm) of the 1-element Cs₂HfCl₆ single crystals.

FIG. 13 depicts the projected highest occupied molecular orbital (HOMO) and lowest unoccupied molecular orbital (LUMO) of the spin-allowed and parity-allowed optical transition for [SnCl₆]²⁻, [ZrCl₆]²⁻, [HfCl₆]²⁻, [TeCl₆]²⁻, and [PtCl₆]²⁻ octahedral molecules as a representation of the energy landscape in the 5-element ZrSnTeHfPt single crystals.

FIG. 14A depicts the PLE map and FIG. 14B depicts line spectrum (monitored at the peak emission wavelength of 728 nm) of the 6-element ZrSnTeHfRePt single crystals. The PLE results prove energy transfer behavior in these crystals by showing that the excited state origin of the NIR emission band is from [TeCl₆]²⁻, [ReCl₆]²⁻, and/or [PtCl₆]²⁻ octahedral molecules depending on the excitation wavelength. Features corresponding to these 3 octahedral molecules are highlighted in FIG. 14B.

FIG. 15 depicts the projected HOMO and LUMO of the spin-allowed and parity-allowed optical transition (with the exception of the Re4+ d-d transition) for [SnCl₆]²⁻, [ZrCl₆]²⁻, [HfCl₆]²⁻, [TeCl₆]²⁻, [PtCl₆]²⁻, and [ReCl₆]²⁻ octahedral molecules as a representation of the energy landscape in the 6-element ZrSnTeHfRePt single crystals.

FIG. 16 depicts ligand-free GD Cs₂TeCl₆, Cs₂TeCl₃Br₃, Cs₂TeBr₆, Cs₂TeBr₃I₃, and Cs₂TeI₆ inks (back) and the respective bulk Cs₂TeCl₆, Cs₂TeBr₆, and Cs₂TeI₆ powders (front) used to fabricate them.

FIGS. 17A-17I depict examples of applications of the inks. FIG. 17A depicts thin films produced by dropcasting Cs₂TeCl₆-DMSO, Cs₂TeBr₆-DMSO, and Cs₂TeI₆-DMF inks, respectively, onto a heated glass substrate with an anti-solvent. FIG. 17B depicts strong yellow emission from a Cs₂TeCl₆ thin film under UV excitation (λₑₓ=302 nm). FIG. 17C depicts photoluminescence spectra of a Cs₂TeCl₆ thin film and Cs₂TeCl₆ coating compared with that of the respective Cs₂TeCl₆ powder. FIGS. 17D-17F depict coatings produced by spraying Cs₂TeCl₆-DMSO (FIG. 17D), Cs₂TeBr₆-DMSO (FIG. 17E), and Cs₂TeI₆-DMF (FIG. 17F) inks, respectively, onto laboratory cellulose wipes and drying with heat. The same results are achieved via painting the inks onto the wipes. FIG. 17G depicts strong yellow emission from a Cs₂TeCl₆ coating under UV excitation (λₑₓ=302 nm). FIGS. 17H-17I depict patterning achieving by stamping Cs₂TeBr₆-DMSO (FIG. 17H) and Cs₂TeI₆-DMF (FIG. 17I) inks, respectively, onto heated rice paper.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

The terms “about” or “approximate” and the like are synonymous and are used to indicate that the value modified by the term has an understood range associated with it, where the range can be ±20%, ±15%, ±10%, ±5%, or ±1%. The terms “substantially” and the like are used to indicate that a value is close to a targeted value, where close can mean, for example, the value is within 80% of the targeted value, within 85% of the targeted value, within 90% of the targeted value, within 95% of the targeted value, or within 99% of the targeted value.

As used herein with respect to a parameter, the term “decreased” or “decreasing” or “decrease” or “reduced” or “reducing” or “reduce” or “lower” refers to a detectable (such as at least about 5%, 10%, 15%, 20%, 25%, 30%, 35%, 40%, 45%, 50%, 55%, 60%, 65%, 70%, 75%, 80%, 85%, 90%, 95%, 96%, 97%, 98%, 99%, or 100%) negative change in the parameter from a comparison control, such as an established normal or reference level of the parameter, or an established standard control. Accordingly, the terms “decreased,” “reduced,” and the like encompass both a partial reduction and a complete reduction compared to a control.

As used herein with respect to a parameter, the term “increased” or “increasing” or “increase” or “enhanced” or “enhancing” or “enhance” or “greater” refers to a detectable (such as at least about 5%, 10%, 15%, 20%, 25%, 30%, 35%, 40%, 45%, 50%, 55%, 60%, 65%, 70%, 75%, 80%, 85%, 90%, 95%, 100%, 200%, 300%, 400%, 500%, 600%, 700%, 800%, 900%, or 1000%) positive change in the parameter from a comparison control, such as an established normal or reference level of the parameter, or an established standard control.

### A. High-Entropy Halide Perovskite Materials

Traditionally, high-entropy material requires extremely high synthesis temperatures (typically above 1000 degrees Celsius). This extensive energy input makes it challenging to scale up the production of high-entropy materials for large-scale applications. Furthermore, even under these conditions, the formation of a high-entropy material system is not necessarily guaranteed, as literature contains countless examples of synthesis designs with five or more components that do not yield high-entropy materials. To overcome the shortcomings of the existing technologies, the new HES material systems provided herein include the design of synthetic procedures using significantly milder conditions. Due to their soft, easily reconfigurable lattices and facile, low-to-mild temperature-solution processability, halide-based perovskites contributes to the design. The vacancy-ordered double-perovskite Cs₂MCl₆ crystal structure can be used as a platform for the creation of high-entropy halide perovskite semiconductor single crystals, e.g., those within the Cs₂{ZrSnTeHfRePt}₁Cl₆ and Cs₂{SnTeReOsIrPt}₁Cl₆ HES families, using room-temperature-solution (20° C.) and low-temperature-solution (80° C.) syntheses.

A high-entropy material according to the formula Cs₂{M}Cl₆ is provided. {M} is a combination of at least five (e.g., 5, 6, 7, or more) metal cations each occupying the M-site of the high-entropy material as a random alloy. The at least five metal cations can occupy the M-site in near-equimolar ratios.

The high-entropy material can comprise a single phase single crystal. For example, the single-phase halide perovskite systems provided herein can contain near-equimolar ratios of disordered at least five (e.g., 5, 6, or more) different [M⁴⁺Cl₆]²⁻ octahedra within each single-domain of the cubic Cs₂MCl₆ crystal framework.

At least five (e.g., 5, 6, 7, or more) metal cations can be tetravalent metal cations selected from the group consisting of Zr⁴⁺, Sn⁴⁺, Te⁴⁺, Hf⁴⁺, Re⁴⁺, Os⁴⁺, Ir⁴⁺, and Pt⁴⁺.

In specific embodiments, the M comprises Sn⁴⁺, Te⁴⁺, Re⁴⁺, Ir⁴⁺ and Pt⁴⁺. For example, the high-entropy material can have the formula: Cs₂{SnTeReOsIrPt}₁Cl₆ or Cs₂{SnTeReOsIrPt}₁Cl₆. Sn, Te, Re, Os, Ir, and Pt in Cs₂{SnTeReOsIrPt}₁Cl₆, or Sn, Te, Re, Os, Ir, and Pt in Cs₂{SnTeReOsIrPt}₁Cl₆ can be in near equimolar ratios. For example, the high-entropy material can be according to the formula: Cs₂Sn_{0.198}Te_{0.218}Re_{0.230}Ir_{0.117}Pt_{0.237}Cl₆ or Cs₂Sn_{0.208}Te_{0.181}Re_{0.166}Os_{0.186}Ir_{0.114}Pt_{0.146}Cl₆.

In some embodiments, the M comprises Zr⁴⁺, Sn⁴⁺, Te⁴⁺, Hf⁴⁺, and Pt⁴⁺. In some embodiments, the high-entropy material has the formula: Cs₂{ZrSnTeHfPt}₁Cl₆ or Cs₂{ZrSnTeHfRePt}₁Cl₆. In some embodiments, the high-entropy material has the formula: Cs₂Zr_{0.266}Sn_{0.147}Te_{0.208}Hf_{0.159}Pt_{0.220}Cl₆ or Cs₂Zr_{0.237}Sn_{0.125}Te_{0.183}Hf_{0.129}Re_{0.142}Pt_{0.185}Cl₆. A crystallographic table for example high-entropy 5-element SnTeReIrPt and 6-element SnTeReOsIrPt perovskite single crystals are provided as Table 1. A crystallographic table for example high-entropy 5-element ZrSnTeHfPt and 6-element ZrSnTeHfRePt perovskite single crystals are provided as Table 2.

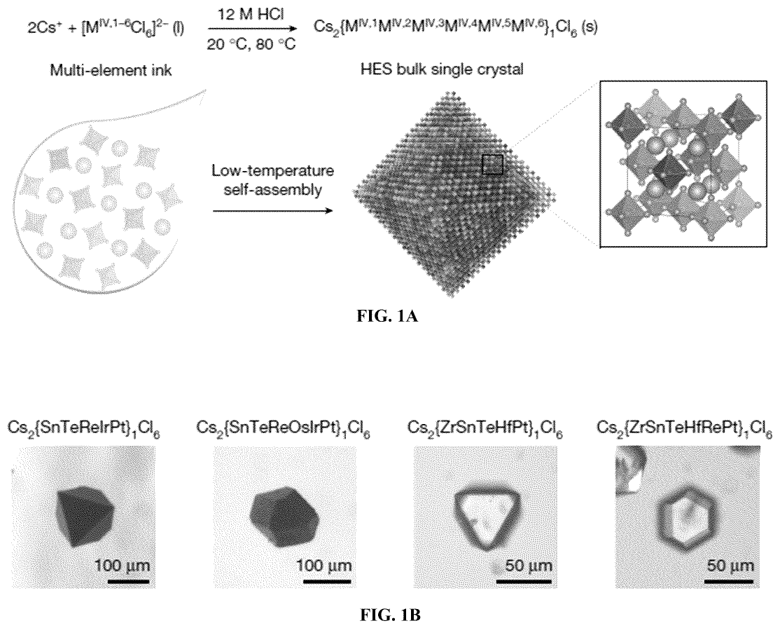

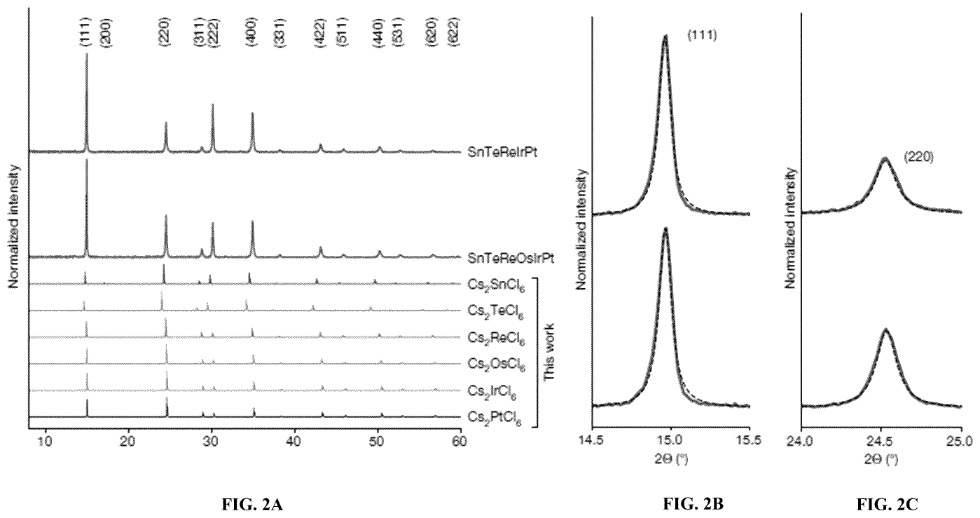

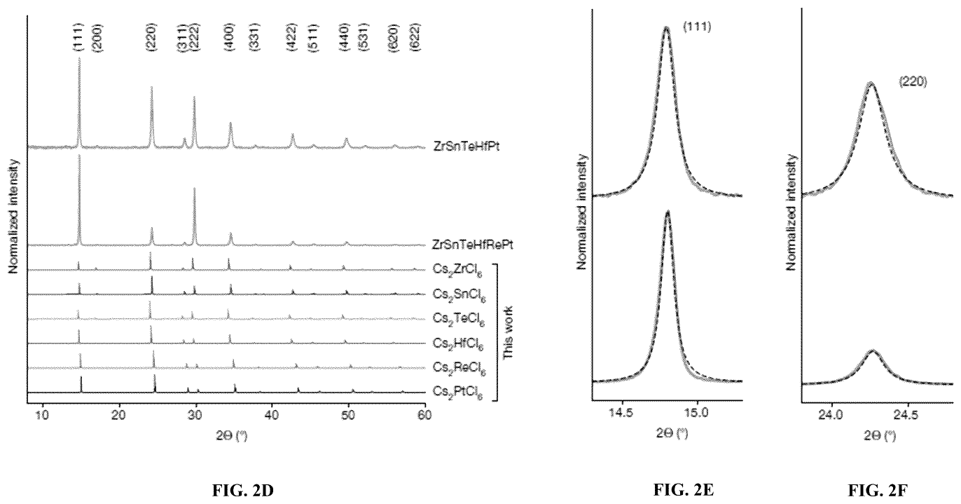

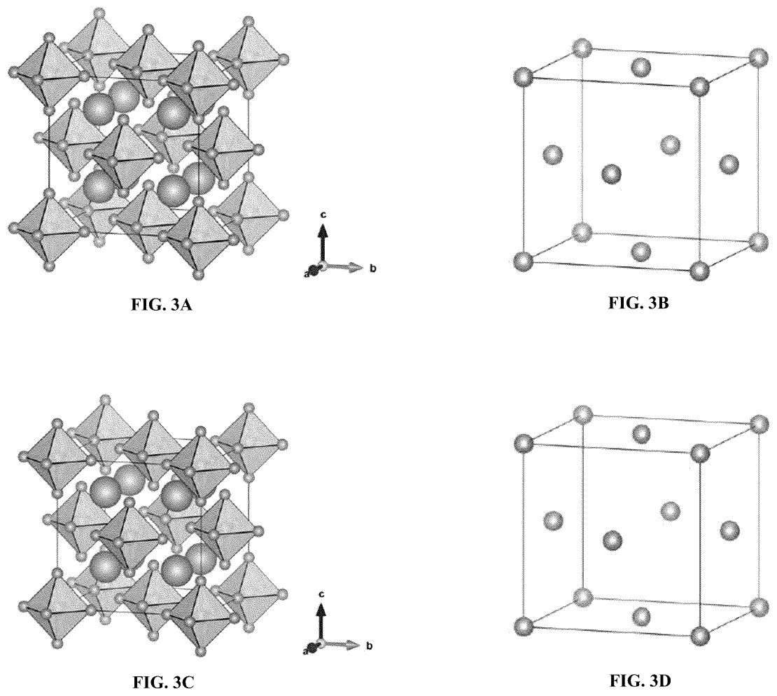

The high-entropy materials provided herein, e.g., five-element SnTeReIrPt, six-element SnTeReOsIrPt, five-element ZrSnTeHfPt and six-element ZrSnTeHfRePt single crystals, can be in the order of 30-100 m in size and possess octahedral and cuboctahedral morphologies typical of a face-centered cubic (FCC) crystal structure, for example as shown in FIG. 1B. PXRD patterns of the halide perovskite single crystals can show single-phase FCC crystal structures across all four compositions for example as shown in FIGS. 2A and 2D. Fine scans over the two prominent FCC reflections (111) and (220) highlight no peak splitting and are well fit with a single Lorentzian function as expected for diffraction peaks of a single-phase crystal system, as shown in FIGS. 2B-2C for example SnTeReIrPt and SnTeReOsIrPt crystals and FIGS. 2E-2F for example ZrSnTeHfPt and ZrSnTeHfRePt crystals. The lattice parameters of the HES compositions can be consistent with those of the constituent one-element single crystals for example as shown in FIGS. 2A and 2D. As shown in Tables 1-2, the five-element SnTeReIrPt, six-element SnTeReOsIrPt, five-element ZrSnTeHfPt, and six-element ZrSnTeHfRePt single crystals can have the cubic Fm3m space group with lattice parameters of about 10.3-10.4 Å, as assessed by SCXRD. Different octahedron types can occupy crystallographically equivalent positions in the SCXRD-determined unit cell such that the resulting crystal structure is a FCC lattice of randomly alloyed M-sites (see, for example, FIGS. 3A-3D). Two-element single crystals (low-entropy) and three- and four-element single crystals (medium-entropy) of their high-entropy counterparts can also have phase-pure FCC crystal structures with lattice parameters in line with the constituent one-element single crystals.

The single-phase FCC crystal systems can contain the five and six different M-site octahedral centers. EDX mapping (FIG. 4) and spectrum of a high-entropy six-element SnTeReOsIrPt single-crystal indicate the incorporation of all six elements homogeneously distributed within one single-crystal domain. EDX analysis of high-entropy five-element SnTeReIrPt, five-element ZrSnTeHfPt, and six-element ZrSnTeHfRePt single crystals similarly confirmed the presence and homogeneous distribution of the expected five, five and six M-site elements, respectively. The EDX spectra yield an approximate Cs:Cl molar ratio of 2:6 for all four HES compositions, with inductively coupled plasma atomic emission spectroscopy (ICP-AES) used for precise quantification of the molar ratio of the five and six different M-site metal centers. High-entropy five-element SnTeReIrPt, six-element SnTeReOsIrPt, five-element ZrSnTeHfPt, and six-element ZrSnTeHfRePt single crystals exhibited near-equimolar ratios among the constituent five and six M-site elements (Table 5). Furthermore, the ICP-AES results across all four HES compositions indicate an approximate Cs:overall M-site cation (that is, all five or six different M-site cations treated as a single M-site cation) molar ratio of 2:1. The stoichiometric values of the Cs cation, overall M-site cation and Cl anion in the formula unit can be approximately two, one and six, respectively. Example precise experimentally determined stoichiometric compositions for the four HES crystal systems are shown in Table 6. The HES crystal structures provided herein can possess five or more (e.g., 5, 6, 7, or more) different M-site octahedral centers in near-equimolar ratios within an overall Cs₂MCl₆ vacancy-ordered double-perovskite framework.

As confirmed by absorption edge-based diffraction experiments and Raman spectroscopy analysis, the metal cations M can be present within the unit cell of the halide perovskite Cs₂{M}Cl₆ single-crystal.

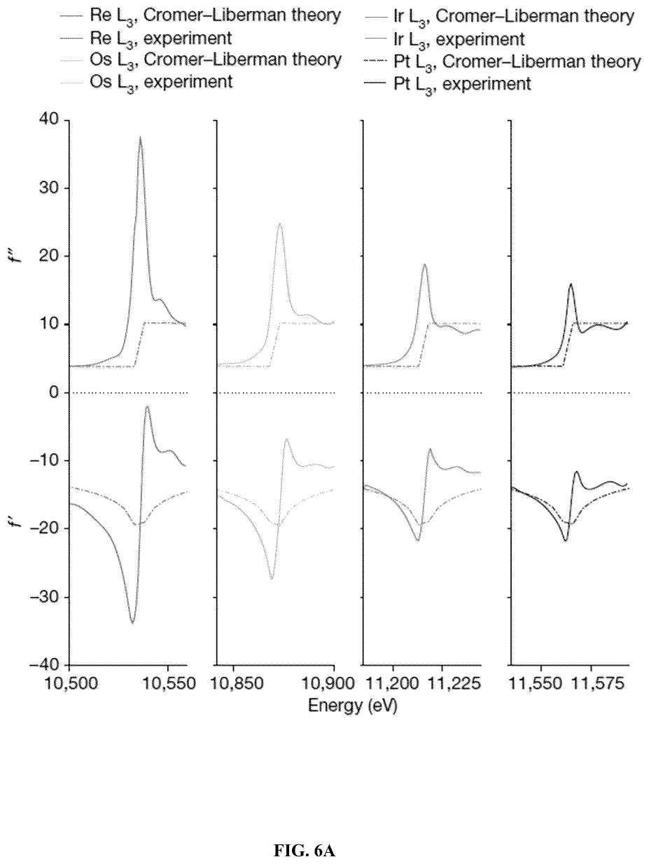

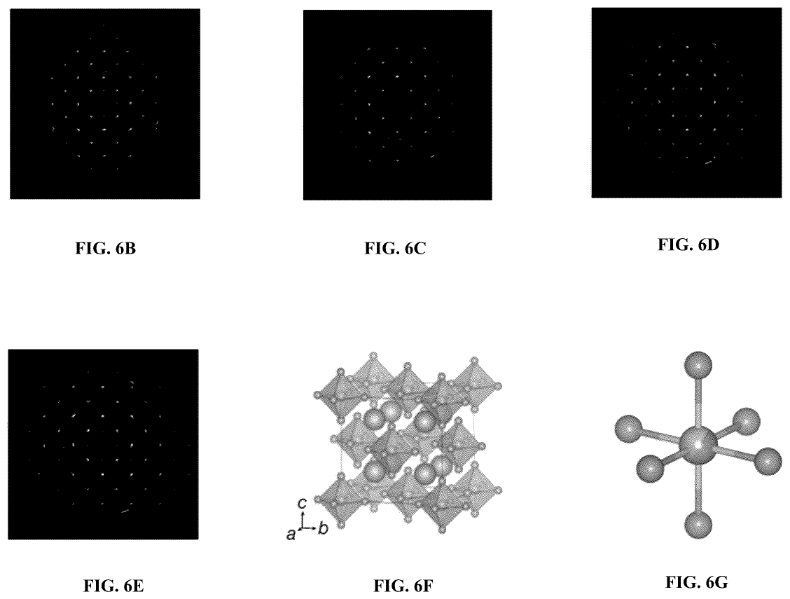

To visualize the absolute configuration of the six different [MCl₆]²⁻ octahedra in this unit cell, the MAD precession images generated from the 0kl plane collected near the L₃ edges of Re, Os, Ir and Pt were analyzed, all of which show a FCC lattice (FIGS. 6B-6E). If any of the four metals are arranged with any local order, the edges of the diffraction patterns would shift away from the overall FCC lattice. Therefore, the preservation of the FCC lattice observed at all edges in all four precession images indicates that all M-site elements in the six-element SnTeReOsIrPt single-crystal are randomly distributed in the unit cell and across the crystal structure (FIGS. 6F, 6G). From this more highly resolved structural information, the occupancy of the four probed metals on the M-site can be determined due to the relationship between site occupancy and f″ and f′. The occupancy of each metal is close to the expected value of one at its characteristic absorption edge (Table 7), and these occupancy values allow for the derivation of M-site metal ratios to ultimately provide elemental information complementary to the ICP-AES results of the six-element SnTeReOsIrPt single-crystal (Table 8). Similar X-ray absorption behavior and similar X-ray scattering behavior and overall structural insights were observed in the MAD analysis of a six-element ZrSnTeHfRePt single crystal (Tables 9-10).

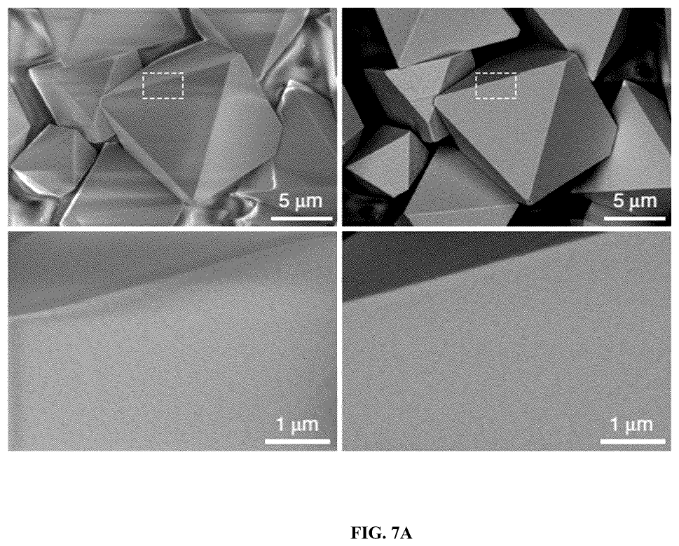

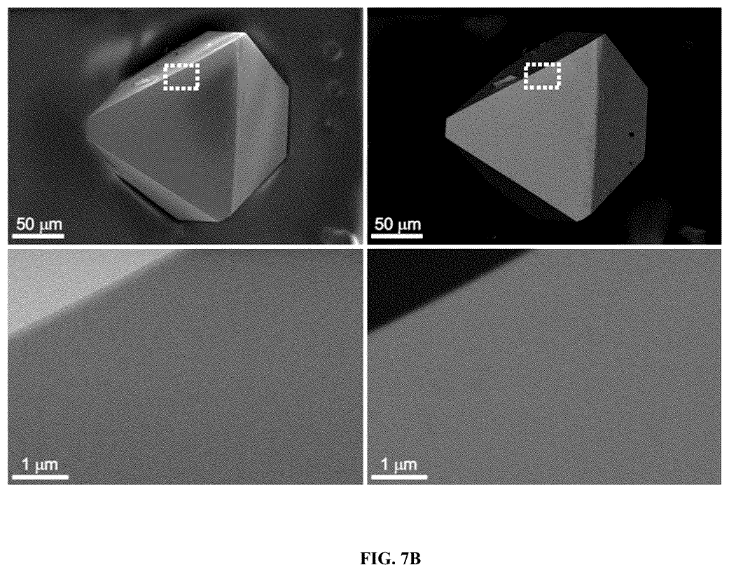

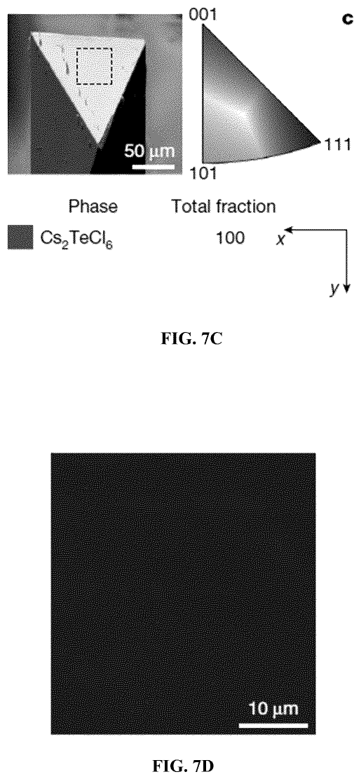

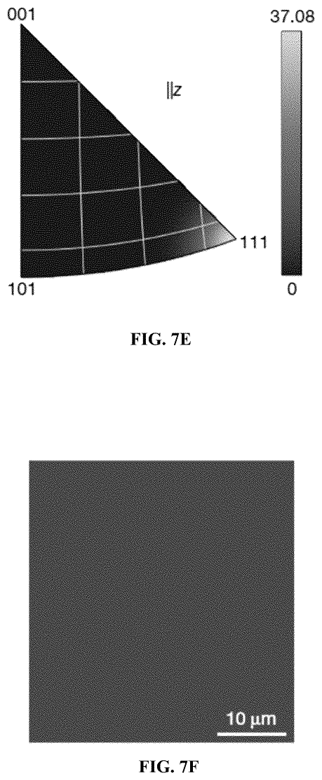

Further, as shown in FIGS. 7A-7F, the combined BSE imaging and EBSD analyses can establish that the HES systems provided herein are indeed single crystals of disordered constituent [MCl₆]²⁻ octahedra with no microstructure, which corroborates the MAD structural evidence provided in this disclosure.

Without wishing to be bound by theory, formation mechanism of high-entropy five-element Cs₂{SnTeReIrPt}₁Cl₆, six-element Cs₂{SnTeReOsIrPt}₁Cl₆, five-element Cs₂{ZrSnTeHfPt}₁Cl₆ and six-element Cs₂{ZrSnTeHfRePt}₁Cl₆ single crystals is as follows. The apparent thermodynamic stability and spontaneous mixing of both five- and six-element HES single crystals is likely due to their lower Gibbs free energy of formation (ΔGmix) as compared with all other single crystals provided herein (which includes one-, two-, three- and four-element single crystals), and even as compared with phase-segregated or amorphous systems. The Gibbs free energy of formation depends on the entropy of mixing (ΔGmix=ΔHmix−TΔSmix, where ΔHmix is the enthalpy of mixing, T is the temperature, and ΔSmix is the entropy of mixing), and the entropy of mixing is partially determined by the configurational entropy of the system. Because configurational entropy relies on the number of microstates or constituent components/particles in a system, packing more elements into the multi-element inks and into the resulting crystal structures of the five- and six-element HES compositions corresponds to a higher configurational entropy contribution to the entropy of mixing. This in turn results in a higher entropy of mixing term and a more negative (lower) Gibbs free energy of formation for HES compositions as compared with other products. As a point of reference, the Gibbs free energy of formation, the entropy of mixing and the enthalpy of mixing have been reported for the Cs₂Sn₁₋ₓTeₓCl₆ (x=0-1) system. For the Cs₂Sn₃Te₃Cl₆ composition (which is equivalent to low-entropy two-element SnTe single crystals reported here), the Gibbs free energy of formation is calculated to be approximately −24 meV per formula unit. Therefore, the Gibbs free energy of formation will continue to decrease below this value (below −24 meV per formula unit) with an increasing number of elements (three, four, five or six) on the M-site in the Cs₂{SnTeReOsIrPt}₁Cl₆ HES family. Similar behavior is expected for the Cs₂{ZrSnTeHfRePt}₁Cl₆ HES family.

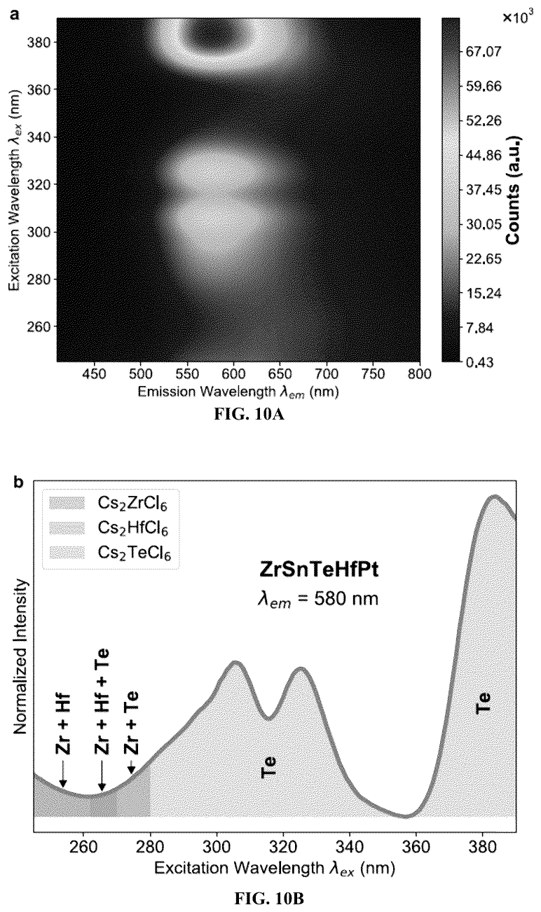

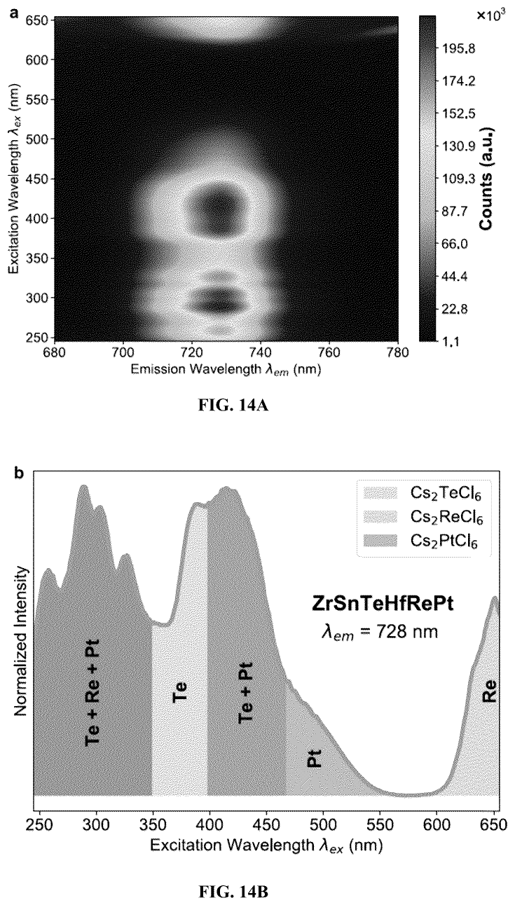

Both five- and six-element HES single crystals, including high-entropy five-element Cs₂{SnTeReIrPt}₁Cl₆, six-element Cs₂{SnTeReOsIrPt}₁Cl₆, five-element Cs₂{ZrSnTeHfPt}₁Cl₆, and six-element Cs₂{ZrSnTeHfRePt}₁Cl₆ single crystals, have enhanced stability and durability comparable to the one-element Cs₂MX6 (M=Te⁴⁺, Sn⁴⁺, Ti⁴⁺, Pt⁴⁺, Pd⁴⁺ and so on; X=Cl−, Br−, I−) systems over the more traditional CsMX3 (M=Pb2+, Sn2+, Ge2+; X=Cl−, Br−, I−) systems. Specifically, five- and six-element HES single crystals maintain the enhanced air, water, UV, electron beam, or temperature stability of some one-element Cs₂MCl₆ crystals. For example, HES single crystals provided herein, such as Cs₂{SnTeReIrPt}₁Cl₆, Cs₂{SnTeReOsIrPt}₁Cl₆, Cs₂{ZrSnTeHfPt}₁Cl₆, and Cs₂{ZrSnTeHfRePt}₁Cl₆ single crystals are stable in air for at least 6 months, which is tested by simply storing all four HES compositions under ambient conditions on a benchtop. (As a precaution, however, all crystals are typically stored in an inert environment such as a vacuum desiccator.) HES single crystals provided herein, including Cs₂{SnTeReIrPt}₁Cl₆, Cs₂{SnTeReOsIrPt}₁Cl₆, Cs₂{ZrSnTeHfPt}₁Cl₆, and Cs₂{ZrSnTeHfRePt}₁Cl₆ single crystals, can be stable for up to 100° C., up to 200° C., up to 300° C., or at higher temperatures. Furthermore, five-element Cs₂{ZrSnTeHfPt}₁Cl₆ single crystals and six-element Cs₂{ZrSnTeHfRePt}₁Cl₆ single crystals are emission stable under constant UV excitation for approximately 11 h (reference the PLE mapping results in FIGS. 10A-10B and 14A-14B). There is no evidence of photoinduced phase segregation in the photoluminescence spectra of these materials during the 11 h period. Finally, five-element Cs₂{SnTeReIrPt}₁Cl₆ single crystals and six-element Cs₂{SnTeReOsIrPt}₁Cl₆ single crystals are stable under all electron beam conditions, but five-element Cs₂{ZrSnTeHfPt}₁Cl₆ single crystals and six-element Cs₂{ZrSnTeHfRePt}₁Cl₆ single crystals exhibit slight electron beam instability under the conditions required for EBSD. Because EBSD requires significantly higher accelerating voltages and beam currents than any other SEM-based measurement technique, the slight electron beam instability under EBSD operating conditions is reasonable. Five-element Cs₂{ZrSnTeHfPt}₁Cl₆ single crystals and six-element Cs₂{ZrSnTeHfRePt}₁Cl₆ HES single crystals are completely stable under all other electron beam conditions, including those for standard secondary electron and BSE imaging and EDX. The stability and durability of the HES single crystals and high entropy semiconductors provided herein enhances the durability and quality of the products using the HES single crystals and high entropy semiconductors provided herein, such as a display, an optoelectronic device, a LED, an electronic device, or a computer chip.

The high-entropy metal halide perovskite single crystals provided herein can have unique optic characteristics (e.g., absorption and emission characteristics) that can be fine-tuned by adjusting the compositions of the HES single crystals. The multiple disordered octahedral units of the HES materials provided herein can serve not only as the vibrational centers but also as the absorbing and emitting centers in these HES crystals, due to the M and Cl orbital character of the highest occupied molecular orbital (HOMO) and lowest unoccupied molecular orbital (LUMO). As a result of this material property, the different isolated [MCl₆]²⁻ octahedra can contribute to the absorption and emission behavior of the HES single crystals. However, not all of the [MCl₆]²⁻ octahedra contained in the HES single crystal may contribute to the absorption and emission behavior.

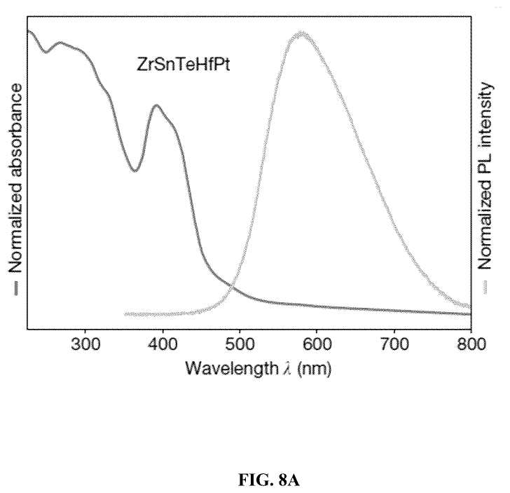

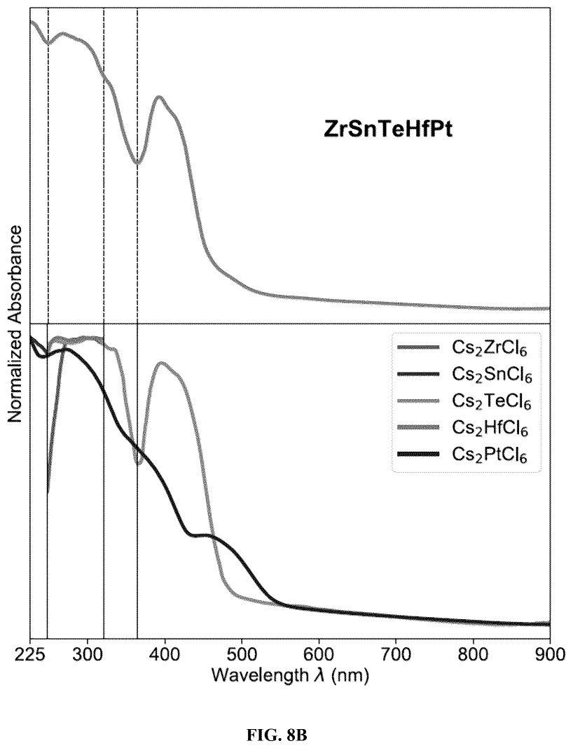

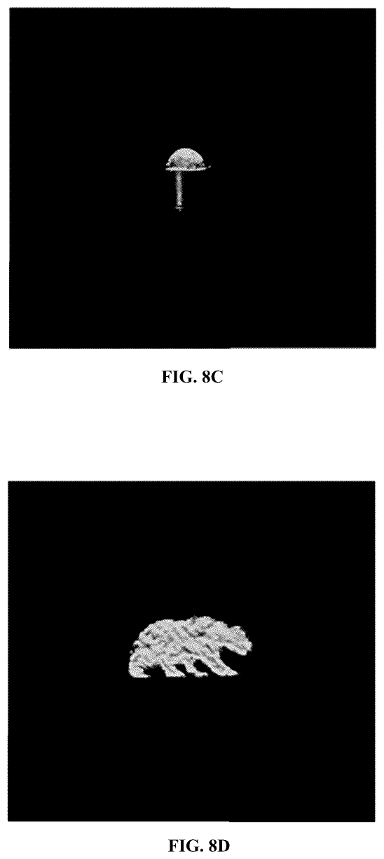

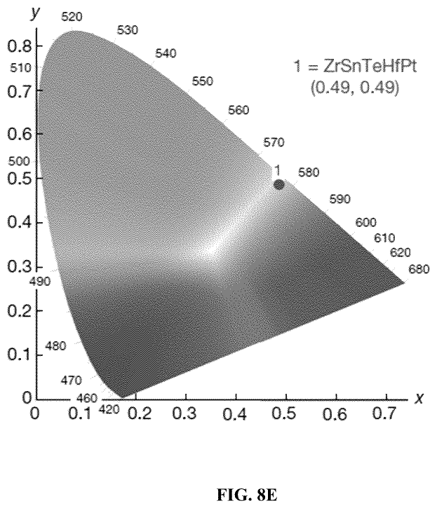

For example, the five-element ZrSnTeHfPt HES composition exhibits gold emission centered at 580 nm (FIGS. 8A, 8C, 8D) with Commission Internationale de l'Eclairage (CIE) chromaticity coordinates of (0.49, 0.49) under 250 nm excitation (FIG. 8E). It is well established in the literature involving Cs₂MCl₆ that one-element Cs₂SnCl₆ single crystals do not emit; that one-element Cs₂ZrCl₆ and Cs₂HfCl₆ single crystals exhibit strong blue emission; that one-element Cs₂TeCl₆ single crystals exhibit yellow emission; and that Cs₂PtCl₆ single crystals exhibit red emission. Therefore, this gold emission (FIGS. 8C, 8D) results from the superposition of the confined exciton yellow emission from [TeCl₆]²⁻ octahedral molecules and the confined exciton red emission from [PtCl₆]²⁻ octahedral molecules. The complete absence of excitonic blue emission from [ZrCl₆]²⁻ and [HfCl₆]²⁻ octahedral molecules in the emission spectrum of this HES composition is potentially indicative of local heterogeneity in the excited-state potential energy surface (due to the disordered nature of the unit cell) affecting the oscillator strength of the parity-allowed ground-state to excited-state transition in [ZrCl₆]²⁻ and [HfCl₆]²⁻ octahedral molecules, coupled with (1) local heterogeneity in the excited-state potential energy surface affecting the efficiency of radiative decay in [ZrCl₆]²⁻ and [HfCl₆]²⁻ octahedral molecules and/or (2) energy transfer behavior from [ZrCl₆]²⁻ and [HfCl₆]²⁻ octahedral molecules to other octahedral centers in these crystals.

The high-entropy material provided herein can be, for example, a powder or an ink. Provided herein are processable semiconductor inks comprising the high-entropy material (e.g., high-entropy halide perovskite single crystals) provided herein. Any of the high-entropy halide perovskite single crystals provided herein can be used or incorporated as a semiconductor ink. For example, provided is a semiconductor ink comprising a high-entropy material according to the formula Cs₂{M}Cl₆, wherein {M} is a combination of at least five metal cations each occupying the M-site of the high-entropy material as a random alloy. For example, provided is a semiconductor ink comprising a high-entropy material according to Cs₂{SnTeReOsIrPt}₁Cl₆, Cs₂{SnTeReOsIrPt}₁Cl₆, Cs₂{ZrSnTeHfPt}₁Cl₆, or Cs₂{ZrSnTeHfRePt}₁Cl₆. Without wishing to be bound by theory, the stabilization of the fundamental perovskite ionic octahedral building blocks in solution creates multifunctional inks with the ability to reversibly transform between the liquid ink and the solid-state perovskite crystalline system in air within a short time period (e.g., minutes). The easily processable perovskite inks can be patterned onto various materials via dropcasting, spraying, painting, or stamping, highlighting the role of solvated octahedral complexes in the rapid formation of phase-pure perovskite structures in ambient conditions. Processable perovskite inks can be used for inkjet printing.

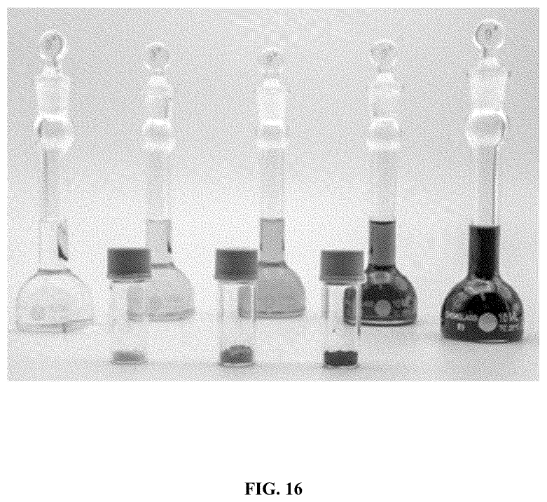

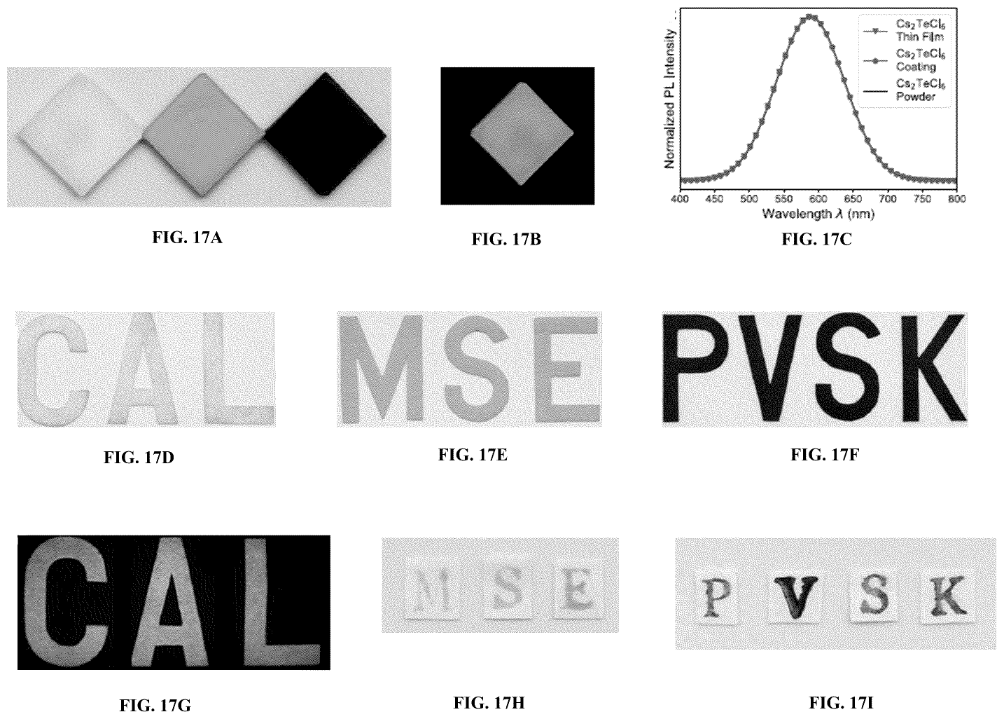

Processable semiconductor inks are described for example in US2024/0218555 and Folgueras et al. Nano Lett. 2021, 21, 8856-8862, the contents of each of which references are incorporated herein by reference in their entirety. For example, FIG. 16 depicts the Cs₂TeCl₆, Cs₂TeCl₃Br₃, Cs₂TeBr₆, Cs₂TeBr₃I₃, and Cs₂TeI₆ inks with the respective bulk Cs₂TeCl₆, Cs₂TeBr₆, and Cs₂TeI₆ powders used to fabricate them. Color tunability from bright yellow (Cs₂TeCl₆—DMSO) to deep orange (Cs₂TeBr₆—DMSO) to black (Cs₂TeI₆—DMF) is observed across the inks. The formation of mixed-halide inks creates a tunable solution-phase composition space from bright yellow to deep orange in Cs₂TeCl₁₋ₓBrₓ (x=0-6) inks, and from deep orange to black in Cs₂TeBr₆₋ₓIₓ (x=0-6) inks. High quality crystalline thin films can be produced directly from the inks via dropcasting onto glass or Si substrates (FIG. 17A), representing the re-assembly of Cs₂TeX₆ crystals from the solution-phase. These thin films possess tunable color like their powder counterparts, from bright yellow for Cs₂TeCl₆ to bright orange for Cs₂TeBr₆ to black for Cs₂TeI₆. The Cs₂TeCl₆ thin film maintains the strong yellow emission (λₑₘ=588 nm) with a photoluminescence quantum yield (PLQY) of 2.06% that is observed in its powder counterpart (FIGS. 17B, 17C). In addition to their use in thin film formation, these inks can also be used in patterning applications, either by spraying or painting on synthetic fibers, or by stamping on rice (Xuan) paper. Microcrystalline dried paints (i.e., coatings) can be produced from the inks by using either a spray airbrush or a paint brush on synthetic fibers such as cellulose wipes (FIGS. 17D-17F). The semiconductor ink transforms within minutes into the solid-phase Cs₂TeX₆ semiconductor coating with the assistance of heat. These coatings possess tunable color like their powder counterparts, and the Cs₂TeCl₆ coating maintains the strong yellow emission (λₑₘ=588 nm, PLQY=2.06%) observed in its powder counterpart (FIG. 17G). Similarly, patterned Cs₂TeX₆ microcrystals can be achieved by coating stamps with the inks and pressing onto heated rice paper (FIGS. 17H, 17I). The solution-phase transforms into the solid-state Cs₂TeX₆ semiconductor within a minute without spreading along the paper, thus achieving Cs₂TeX₆ perovskite patterning through stamping (a form of printing).

Also provided are products comprising the high-entropy material provided herein. The high-entropy materials provided herein can be used as semiconductors, e.g., used for optoelectronic applications (such as LEDs and displays) and electronic applications (such as computer chips). High-entropy semiconductors (HESs) can be produced from the high-entropy material provided herein based on the processable ink chemistry. Tunable light emission can be achieved by adjusting the individual elements of the high-entropy material. The high-entropy semiconductor materials provided herein require low temperature for synthesis (e.g., 100° C. or lower, 80° C. or lower, room temperature), and thus, can be incorporated into electronic devices without destroying other necessary layers that may be incompatible with high temperatures.

TABLE 1
Crystallographic table for the high-entropy 5-element SnTeReIrPt
and 6-element SnTeReOsIrPt perovskite single crystals

| Crystal | Cs₂{SnTeReIrPt}₁Cl₆ | Cs₂{SnTeReOsIrPt}₁Cl₆ |
|---|---|---|
| CSD No. | 2216617 | 2216636 |
| Chemical formula | Cs₂Sn_{0.27}Te0.23Re_{0.21}Ir_{0.16}Pt_{0.13}Cl₆ | Cs₂Sn_{0.24}Te_{0.2}Re_{0.14}Os_{0.18}Ir_{0.13}Pt_{0.1}Cl₆ |
| Formula weight | 635.46 | 638.87 |
| Temperature/K | 293 | 293 |
| Crystal system | Cubic | Cubic |
| Space group | Fm-3m | Fm-3m |
| a/Å | 10.3035(2) | 10.3110(2) |
| b/Å | 10.3035(2) | 10.3110(2) |
| c/Å | 10.3035(2) | 10.3110(2) |
| α/° | 90 | 90 |
| β/° | 90 | 90 |
| γ/° | 90 | 90 |
| Volume/Å³ | 1093.84(6) | 1096.23(6) |
| Z | 4 | 4 |
| ρ_{calc}/g/cm³ | 3.859 | 3.871 |
| μ/mm⁻¹ | 85.548 | 85.281 |
| F(000) | 1103.0 | 1108.0 |
| Crystal size/mm³ | 0.163 × 0.066 × 0.053 | 0.224 × 0.08 × 0.04 |
| Radiation | CuKα (λ = 1.54184) | CuKα (λ = 1.54184) |
| 2θ range for data | 14.892 to 156.148 | 14.882 to 146.464 |
| collection/° | | |
| Index ranges | −12 ≤ h ≤ 6, −8 ≤ | −12 ≤ h ≤ 11, −9 ≤ |
| | k ≤ 12, −12 ≤ l ≤ 11 | k ≤ 10, −11 ≤ l ≤ 9 |
| Reflections collected | 502 | 600 |
| Independent | 84 [Rint = 0.0418, | 83 [Rint = 0.0597, |
| reflections | Rsigma = 0.0207] | Rsigma = 0.0240] |
| Data/restraints/ | 84/0/7 | 83/0/7 |
| parameters | | |
| Goodness-of-fit on | 1.259 | 1.257 |
| F² | | |
| Final R indexes [I ≥ | R₁ = 0.0359, | R₁ = 0.0280, |
| 2σ(I)] | wR₂ = 0.0923 | wR₂ = 0.0706 |
| Final R indexes [all | R₁ = 0.0359, | R₁ = 0.0280, |
| data] | wR₂ = 0.0923 | wR₂ = 0.0706 |
| Largest diff. | 1.02/−1/33 | 1.07/−1.49 |
| peak/hole/e Å⁻³ | | |

TABLE 2
Crystallographic table for the high-entropy 5-element ZrSnTeHfPt
and 6-element ZrSnTeHfRePt perovskite single crystals

| Crystal | Cs₂{ZrSnTeHfPt}₁Cl₆ | Cs₂{ZrSnTeHfRePt}₁Cl₆ |
|---|---|---|
| CSD No. | 2216638 | 2216637 |
| Chemical formula | Cs₂Zr_{0.24}Sn_{0.29}Te_{0.19}Hf_{0.14}Pt_{0.14}Cl₆ | Cs₂Zr_{0.28}Sn_{0.21}Te_{0.16}Hf_{0.14}Re_{0.12}Pt_{0.1}Cl₆ |
| Formula weight | | |
| Temperature/K | 293 | 293 |
| Crystal system | Cubic | Cubic |
| Space group | Fm-3m | Fm-3m |
| a/Å | 611.53 | 615.11 |
| b/Å | 293 | 293 |
| c/Å | Cubic | Cubic |
| α/° | Fm-3m | Fm-3m |
| β/° | 10.3868(3) | 10.3742(2) |
| γ/° | 10.3868(3) | 10.3742(2) |
| Volume/Å³ | 10.3868(3) | 10.3742(2) |
| Z | 90 | 90 |
| ρ_{calc}/g/cm³ | 90 | 90 |
| μ/mm⁻¹ | 90 | 90 |
| F(000) | 1120.59(10) | 1116.51(6) |
| Crystal size/mm³ | 4 | 4 |
| Radiation | 3.625 | 3.659 |
| 2θ range for data | 34.542 to 148.314 | 14.79 to 144.22 |
| collection/° | | |
| Index ranges | −6 ≤ h ≤ 11, −7 ≤ | −11 ≤ h ≤ 11, −9 ≤ |
| | k ≤ 12, −11 ≤ l ≤ 12 | k ≤ 12, −12 ≤ l ≤ 9 |
| Reflections collected | 583 | 595 |
| Independent reflections | 78 [Rint = 0.0827, | 80 [Rint = 0.0536, |
| | Rsigma = 0.0347] | Rsigma = 0.0163] |
| Data/restraints/ | 78/0/6 | 80/0/7 |
| parameters | | |
| Goodness-of-fit on F² | 1.146 | 1.203 |
| Final R indexes [I ≥ 2σ(I)] | R₁ = 0.0426, | R₁ = 0.0280, |
| | wR₂ = 0.1021 | wR₂ = 0.0701 |
| Final R indexes [all data] | R₁ = 0.0427, | R₁ = 0.0280, |
| | wR₂ = 0.1021 | wR₂ = 0.0706 |
| Largest diff. peak/hole/e | 0.84/−1.79 | 0.71/−0.82 |
| Å⁻³ | | |

### B. Generating High-Entropy Halide Perovskite Materials

Methods of generating a high-entropy material provided herein can include contacting Cs⁺ molecules with at least five different [MCl₆]²⁻ molecules in a solvent, forming via a self-assembly process a high-entropy material according to the formula Cs₂{M}Cl₆. The at least five different [MCl₆]²⁻ molecules each contain a different metal cation M. {M} is a combination of the different metal cations each occupying the M-site of the high-entropy material as a random alloy. The method is conducted at a temperature of 100° C. or lower (e.g., at 100° C., 95° C., 90° C., 85° C., 80° C., 75° C. or lower). For example, single crystals in the Cs₂{SnTeReOsIrPt}₁Cl₆ HES family can be produced from an appropriate multi-element ink via a low-temperature (80° C.) reprecipitation synthesis. Single crystals in the Cs₂{ZrSnTeHfRePt}₁Cl₆ HES family can be produced from an appropriate multi-element ink via a room-temperature (20° C.) reprecipitation synthesis.

The one-element Cs₂ZrCl₆, Cs₂SnCl₆, Cs₂TeCl₆, Cs₂HfCl₆, Cs₂ReCl₆, Cs₂OsCl₆, Cs₂IrCl₆ and Cs₂PtCl₆ starting powders can be dissolved into a single, well-mixed 12 M hydrochloric acid (HCl) solution to generate multi-element inks of free Cs+ cations and isolated [MCl₆]²⁻ (M=Zr⁴⁺, Sn⁴⁺, Te⁴⁺, Hf⁴⁺, Re⁴⁺, Os⁴⁺, Ir⁴⁺ or Pt⁴⁺) anionic octahedral molecules. A (re)crystallization process from these multi-element inks can be used to achieve single crystals, e.g., a high-entropy material according to the formula Cs₂{M}Cl₆, where{M} is a combination of at least five (e.g., 5, 6, 7, or more) metal cations each occupying the M-site of the high-entropy material as a random alloy. The at least five metal cations can occupy the M-site in near-equimolar ratios.

The methods can include dissolving at least five different Cs₂MCl₆ powders in the solvent containing chloride (e.g., excess chloride), and the at least five different Cs₂MCl₆ powders each contain a different metal cation M. The solvent can be 12 M HCl. The method can include dissolving the at least five different Cs₂MCl₆ molecules in the solvent at 100° C. with stirring, forming a solution, and letting the solution sit at 80° C. or lower without stirring, forming the high-entropy material. The method can form single phase, single crystals as the high-entropy material.

Building on octahedral ink formation from Cs₂TeX₆ (X=Cl⁻, Br⁻, I⁻) powders, the one-element Cs₂ZrCl₆, Cs₂SnCl₆, Cs₂TeCl₆, Cs₂HfCl₆, Cs₂ReCl₆, Cs₂OsCl₆, Cs₂IrCl₆ and Cs₂PtCl₆ starting powders can be dissolved into a solvent, e.g., a single, well-mixed 12 M hydrochloric acid (HCl) solution to generate multi-element inks of free Cs⁺ cations and isolated [MCl₆]²⁻ (M=Zr⁴⁺, Sn⁴⁺, Te⁴⁺, Hf⁴⁺, Re⁴⁺, Os⁴⁺, Ir⁴⁺ or Pt⁴⁺) anionic octahedral molecules (FIG. 1A). Where no measurable K concentration is present in each Cs₂MCl₆ system following cation exchange, the cation exchange reaction is complete and pure Cs₂MCl₆ systems result from the reaction.

A (re)crystallization process from these multi-element inks (FIG. 1A) can be used to achieve single crystals, e.g., within the Cs₂{SnTeReOsIrPt}₁Cl₆ and Cs₂{ZrSnTeHfRePt}₁Cl₆ HES families. The solution syntheses developed to produce these HES single crystals create high-entropy materials using low-temperature (80° C.) or room-temperature (20° C.) procedures, as compared to the high-temperature procedures of all HEMs, HECs and other HESs. Furthermore, any combination of proposed M-site metal centers can be used to synthesize HES single crystals, thereby generating a library of two-, three-, four-, five- and six-element single crystals. At least five different [MCl₆]²⁻ molecules can be selected from the group consisting of [ZrCl₆]²⁻, [SnCl₆]²⁻[TeCl₆]²⁻, [HfCl₆]²⁻, [ReCl₆]²⁻, [OsCl₆]²⁻, [IrCl₆]²⁻, and [PtCl₆]²⁻.

For example, single crystals in the Cs2{SnTeReOsIrPt}1Cl6 HES family can be produced from an appropriate multi-element ink via a low-temperature (80° C.) reprecipitation synthesis (FIG. 1A). Stoichiometric amounts of Cs2SnCl6, Cs2TeCl6, Cs2ReCl6, Cs2OsCl6, Cs2IrCl6 and Cs2PtCl6 powders can be dissolved in an uncapped vial containing 5 ml of 12 M HCl at 100° C. and 1,000 rpm spin speed (using a magnetic stir bar). An excess chloride environment (as in 12M HCl) promotes the formation of the six coordinated [MCl6]2− octahedral molecules in solution. Once all powders are dissolved, the stir bar can be removed from the solution and the vial can be returned to the hot plate, which is turned down to 80° C. The vial can remain uncapped and at 80° C. during the entire synthesis process. Synthesis is deemed complete when sufficient single crystals are seen at the bottom of the vial and a small amount of acid solution remained. Excess solution is removed, and single crystals are washed with ethanol, blown with N2 gas to dry and stored in a vacuum desiccator. Among precipitates, 100% can be single crystals of the desired single-phase composition. No other structures or products can be formed during any of the syntheses or washing processes.

As another example, single crystals in the Cs₂{ZrSnTeHfRePt}₁Cl₆ HES family can be produced from an appropriate multi-element ink via a room-temperature (20° C.) reprecipitation synthesis (FIG. 1A). Very dilute stoichiometric amounts of Cs₂ZrCl₆, Cs₂SnCl₆, Cs₂TeCl₆, Cs₂HfCl₆, Cs₂ReCl₆ and Cs₂PtCl₆ powders are dissolved in a capped vial containing 20 ml of 12 M HCl at room temperature (20° C.) and 1,000 rpm spin speed (using a magnetic stir bar). An excess chloride environment (e.g., as in 12 M HCl) promotes the formation of the six coordinated [MCl₆]²⁻ octahedral molecules in solution. Once all powders are dissolved, the solution can be left in the capped vial at 20° C. until synthesis is complete. Synthesis is deemed complete when a sufficient amount of single crystals is seen at the bottom of the vial. Excess solution is removed, and single crystals are washed with ethanol, blown with N₂ gas to dry and stored in a vacuum desiccator. Among precipitates, 100% can be single crystals of the desired single-phase composition. No other structures or products can be formed during any of the syntheses or washing processes.

Also provided are high-entropy materials generated by the methods provided herein. The methods provided herein can produce single crystal halide perovskite semiconductors within the Cs₂{SnTeReOsIrPt}₁Cl₆ and Cs₂{ZrSnTeHfRePt}₁Cl₆ HES families. For example, at least five different Cs₂MCl₆ powders of the methods can contain (i) Cs₂SnCl₆, Cs₂TeCl₆, Cs₂ReCl₆, Cs₂IrCl₆, and Cs₂PtCl₆ powders, (ii) Cs₂SnCl₆, Cs₂TeCl₆, Cs₂ReCl₆, Cs₂OsCl₆, Cs₂IrCl₆, and Cs₂PtCl₆ powders, (iii) Cs₂ZrCl₆, Cs₂SnCl₆, Cs₂TeCl₆, Cs₂HfCl₆, and Cs₂PtCl₆ powders, or (iv) Cs₂ZrCl₆, Cs₂SnCl₆, Cs₂TeCl₆, Cs₂HfCl₆, Cs₂ReCl₆ and Cs₂PtCl₆ powders. For example, the methods can include forming the high-entropy material according to the formula Cs₂{SnTeReOsIrPt}₁Cl₆, Cs₂{SnTeReOsIrPt}₁Cl₆, Cs₂{ZrSnTeHfPt}₁Cl₆, or Cs₂{ZrSnTeHfRePt}₁Cl₆. A crystallographic table for example high-entropy 5-element SnTeReIrPt and 6-element SnTeReOsIrPt perovskite single crystals are provided as Table 1. A crystallographic table for example high-entropy 5-element ZrSnTeHfPt and 6-element ZrSnTeHfRePt perovskite single crystals are provided as Table 2. Example precise experimentally determined stoichiometric compositions for the four HES crystal systems are shown in Table 6.

High-entropy materials provided herein can exhibit enhanced intrinsic properties compared to their components alone. For example, Cs₂{SnTeReOsIrPt}₁Cl₆ provided herein can exhibit enhanced intrinsic properties compared to its component Cs₂SnCl₆, Cs₂TeCl₆, Cs₂ReCl₆, Cs₂OsCl₆, Cs₂IrCl₆, or Cs₂PtCl₆ individually alone. Therefore, the high-entropy materials provided herein can be used with improved performance in areas where conventional semiconductors are used. In particular, the lower energy input requirement as well as the faster synthesis procedure is directly related to the economic value and sustainability of the compositions and methods provided herein in comparison to the conventional semiconductor fabrication process. Furthermore, the methods provided herein provide a detailed synthesis route that is highly reproducible and reliable in synthesis. The methods provided herein demonstrates the feasibility of synthesizing high-entropy semiconductor single crystals based on halide perovskite under room temperature (20° C.) and low temperature (80° C.). Careful and comprehensive characterizations are done on the high-entropy halide perovskite materials produced by the methods provided herein to confirm the elemental ratios and phase purity of these materials. Basic optical properties, that is, the absorption and emission properties show their potential uses in optical or optoelectronic applications.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

### EXAMPLES

### Example 1: Synthesis and Characterization of High-Entropy Halide Perovskite Single Crystals

Synthesis of High-Entropy Halide Perovskite Single Crystals Using Cs₂MCl₆ Crystal Structure

The vacancy-ordered double-perovskite Cs₂MCl₆ crystal structure was explored as a platform for the creation of high-entropy halide perovskite semiconductor (HES) single crystals within the Cs₂{ZrSnTeHfRePt}₁Cl₆ and Cs₂{SnTeReOsIrPt}₁Cl₆ HES families using room-temperature-solution (20° C.) and low-temperature-solution (80° C.) syntheses, respectively. These single-phase systems contain near-equimolar ratios of disordered five and six different [M⁴⁺Cl₆]²⁻ octahedra within each single-crystal domain. Confined exciton states form for each [MCl₆]²⁻ octahedral complex within the bulk HES crystal, generating a probability of rapid excitonic relaxation to the more strongly confined exciton states via energy transfer.

Building on octahedral ink formation from Cs₂TeX₆ (X=Cl⁻, Br⁻, I⁻) powders, the one-element Cs₂ZrCl₆, Cs₂SnCl₆, Cs₂TeCl₆, Cs₂HfCl₆, Cs₂ReCl₆, Cs₂OsCl₆, Cs₂IrCl₆ and Cs₂PtCl₆ starting powders were dissolved into a single, well-mixed 12 M hydrochloric acid (HCl) solution to generate multi-element inks of free Cs⁺ cations and isolated [MCl₆]²⁻ (M=Zr⁴⁺, Sn⁴⁺, Te⁴⁺, Hf⁴⁺, Re⁴⁺, Os⁴⁺, Ir⁴⁺ or Pt⁴⁺) anionic octahedral molecules (FIG. 1A). Crystallographic characteristics of the 1-element Cs₂ZrCl₆, Cs₂SnCl₆, Cs₂TeCl₆, Cs₂HfCl₆, Cs₂ReCl₆, Cs₂OsCl₆, Cs₂IrCl₆ and Cs₂PtCl₆ perovskite single crystals are provided in Tables 3-4. PXRD patterns of 1-element Cs₂ZrCl₆, Cs₂SnCl₆, Cs₂TeCl₆, Cs₂HfCl₆, Cs₂ReCl₆, Cs₂OsCl₆, Cs₂IrCl₆ and Cs₂PtCl₆ perovskite powders indicated phase-pure FCC crystal structures. Molar concentration results of inductively coupled plasma atomic emission spectroscopy (ICP-AES) for 1-element Cs₂ZrCl₆, Cs₂SnCl₆, Cs₂TeCl₆, Cs₂HfCl₆, Cs₂ReCl₆, Cs₂OsCl₆, Cs₂IrCl₆ and Cs₂PtCl₆ perovskite powders revealed no measurable K concentration in each Cs₂MCl₆ system following cation exchange, thus confirming that the cation exchange reaction is complete and that pure Cs₂MCl₆ systems result from the reaction.

A (re)crystallization process from these multi-element inks (FIG. 1A) was used to achieve single crystals within the Cs₂{SnTeReOsIrPt}₁Cl₆ and Cs₂{ZrSnTeHfRePt}₁Cl₆ HES families. The Cs₂{SnTeReOsIrPt}₁Cl₆ HES family spans low-entropy two-element Cs₂{SnTe}₁Cl₆ (SnTe); medium-entropy three-element Cs₂{SnTePt}₁Cl₆ (SnTePt) and four-element Cs₂{SnTeIrPt}₁Cl₆ (SnTeIrPt); and high-entropy five-element Cs₂{SnTeReIrPt}₁Cl₆ (SnTeReIrPt) and six-element Cs₂{SnTeReOsIrPt}₁Cl₆ (SnTeReOsIrPt) single crystals. The Cs₂{ZrSnTeHfRePt}₁Cl₆ HES family spans low-entropy two-element Cs₂{ZrHf}₁Cl₆ (ZrHf); medium-entropy three-element Cs₂{ZrTeHf}₁Cl₆ (ZrTeHf) and four-element Cs₂{ZrSnTeHf}₁Cl₆ (ZrSnTeHf); and high-entropy five-element Cs₂{ZrSnTeHfPt}₁Cl₆ (ZrSnTeHfPt) and six-element Cs₂{ZrSnTeHfRePt}₁Cl₆ (ZrSnTeHfRePt) single crystals.

The solution syntheses developed to produce these HES single crystals create high-entropy materials using either room-temperature (20° C.) or low-temperature (80° C.) procedures, as compared to the high-temperature procedures of all HEMs, HECs and other HESs. Furthermore, any combination of proposed M-site metal centers can be used to synthesize HES single crystals, thereby generating a library of two-, three-, four-, five- and six-element single crystals.

TABLE 3
Crystallographic table for the 1-element Cs₂ZrCl₆, Cs₂SnCl₆, Cs₂TeCl₆,
and Cs₂HfCl₆ perovskite single crystals

| | | | | |
|---|---|---|---|---|
| Crystal | Cs₂ZrCl₆ | Cs₂SnCl₆ | Cs₂TeCl₆ | Cs₂HfCl₆ |
| CSD No. | 2216616 | 2216627 | 2216615 | 2216620 |
| Chemical formula | Cs₂ZrCl₆ | Cs₂SnCl₆ | Cs₂TeCl₆ | Cs₂HfCl₆ |
| Formula weight | 569.74 | 597.21 | 606.12 | 657.01 |
| Temperature/K | 293 | 293 | 293 | 293 |
| Crystal system | Cubic | Cubic | Cubic | Cubic |
| Space group | Fm-3m | Fm-3m | Fm-3m | Fm-3m |
| a/Å | 10.4544(6) | 10.3743(3) | 10.4754(4) | 10.4120(6) |
| b/Å | 10.4544(6) | 10.3743(3) | 10.4754(4) | 10.4120(6) |
| c/Å | 10.4544(6) | 10.3743(3) | 10.4754(4) | 10.4120(6) |
| α/° | 90 | 90 | 90 | 90 |
| β/° | 90 | 90 | 90 | 90 |
| γ/° | 90 | 90 | 90 | 90 |
| Volume/Å³ | 1142.6(2) | 1116.55(10) | 1149.51(13) | 1128.8(2) |
| Z | 4 | 4 | 4 | 4 |
| ρ_{calc}/g/cm³ | 3.312 | 3.553 | 3.502 | 3.866 |
| μ/mm⁻¹ | 8.576 | 10.080 | 10.157 | 16.949 |
| F(000) | 1008.0 | 1048.0 | 1056.0 | 1136.0 |
| Crystal size/mm³ | 0.058 × 0.055 × | 0.25 × 0.13 × | 0.242 × 0.21 × | 0.05 × 0.04 × |
| | 0.053 | 0.09 | 0.091 | 0.03 |
| Radiation | MoKα (λ = | MoKα (λ = | MoKα (λ = | MoKα (λ = |
| | 0.71073) | 0.71073) | 0.71073) | 0.71073) |
| 2θ range for data | 6.75 to 61.764 | 6.802 to 55.864 | 6.738 to 56.552 | 6.778 to 52.512 |
| collection/° | | | | |
| Index ranges | −13 ≤ h ≤14, | −13 ≤ h ≤ 12, | −8 ≤ h ≤ 13, | −10 ≤ h ≤ 12, |
| | −7 k ≤ 13, | −11 ≤ k ≤ 13, | −13 ≤ k ≤ 13, | −12 ≤ k ≤ 12, |
| | −14 ≤ l ≤10 | −13 ≤ l ≤ 12 | −8 ≤ l ≤ 13 | −5 ≤ l ≤ 12 |
| Reflections collected | 788 | 1815 | 725 | 559 |
| Independent reflections | 113 [Rint = 0.0220, | 98 [Rint = 0.0305, | 101 [Rint = 0.0166, | 82 [Rint = 0.0200, |
| | Rsigma = 0.0161] | Rsigma = 0.0095] | Rsigma = 0.0068] | Rsigma = 0.0123] |
| Data/restraints/parameters | 113/0/7 | 98/0/7 | 101/0/7 | 82/0/6 |
| Goodness-of-fit on F² | 1.234 | 1.265 | 1.143 | 1.162 |
| Final R indexes [I ≥ 2σ(I)] | R₁ = 0.0142, | R₁ = 0.0151, | R₁ = 0.0105, | R₁ = 0.0165, |
| | wR₂ = 0.0323 | wR₂ = 0.0313 | wR₂ = 0.0279 | wR₂ = 0.0382 |
| Final R indexes | R₁ = 0.0157, | R₁ = 0.0151, | R₁ = 0.0107, | R₁ = 0.0206, |
| [all data] | wR₂ = 0.0328 | wR₂ = 0.0313 | wR₂ = 0.0279 | wR₂ = 0.0392 |
| Largest diff. peak/hole/ | 0.37/−0.61 | 0.33/−0.67 | 0.25/−0.29 | 0.97/−0.43 |
| e Å⁻³ | | | | |

TABLE 4
Crystallographic table for the 1-element Cs₂ReCl₆, Cs₂OsCl₆, Cs₂IrCl₆, and Cs₂PtCl₆ perovskite single crystals

| Crystal | Cs₂ReCl₆ | Cs₂OsCl₆ | Cs₂IrCl₆ | Cs₂PtCl₆ |
|---|---|---|---|---|
| CSD No. | 2216626 | 2216618 | 2216624 | 2216614 |
| Chemical formula | Cs₂ReCl₆ | Cs₂OsCl₆ | Cs₂IrCl₆ | Cs₂PtCl₆ |
| Formula weight | 664.72 | 668.72 | 670.72 | 673.61 |
| Temperature/K | 293 | 293 | 293 | 293 |
| Crystal system | Cubic | Cubic | Cubic | Cubic |
| Space group | Fm-3m | Fm-3m | Fm-3m | Fm-3m |
| a/Å | 10.2725(4) | 10.2323(10) | 10.2140(2) | 10.2152(2) |
| b/Å | 10.2725(4) | 10.2323(10) | 10.2140(2) | 10.2152(2) |
| c/Å | 10.2725(4) | 10.2323(10) | 10.2140(2) | 10.2152(2) |
| α/° | 90 | 90 | 90 | 90 |
| β/° | 90 | 90 | 90 | 90 |
| γ/° | 90 | 90 | 90 | 90 |
| Volume/Å³ | 1084.00(13) | 1071.32(3) | 1065.58(6) | 1065.96(6) |
| Z | 4 | 4 | 4 | 4 |
| ρ_{calc}/g/cm³ | 4.073 | 4.146 | 4.181 | 4.197 |
| μ/mm⁻¹ | 19.235 | 20.023 | 90.031 | 90.375 |
| F(000) | 1148.0 | 1152.0 | 1156.0 | 1160.0 |
| Crystal size/mm³ | 0.579 × | 0.14 × | 0.128 × | 0.223 × |
| | 0.122 × 0.08 | 0.09 × 0.08 | 0.048 × 0.034 | 0.08 × 0.04 |
| Radiation | MoKα | MoKα | CuKα | CuKα |
| | (λ = 0.71073) | (λ = 0.71073) | (λ = 1.54184) | (λ = 1.54184) |
| 2θ range for data | 6.87 to 56.466 | 6.898 to 60.752 | 15.024 to 150.288 | 15.022 to 148.948 |
| collection/° | | | | |
| Index ranges | −13 ≤ h ≤ 7, −13 ≤ | −14 ≤ h ≤ 14, −14 ≤ | −10 ≤ h ≤ 8, −12 ≤ | −12 ≤ h ≤ 9, −11 ≤ |
| | k ≤ 11, −12 ≤ l ≤ 12 | k ≤ 14, −14 ≤ l ≤ 14 | k ≤ 12, −10 ≤ l ≤ 12 | k ≤ 12, −11 ≤ l ≤ 10 |
| Reflections | 816 | 16953 | 560 | 565 |
| collected | | | | |
| Independent | 98 [Rint = 0.0273, | 115 [Rint = 0.0317, | 80 [Rint = 0.0433, | 80 [Rint = 0.0948, |
| reflections | Rsigma = 0.0140] | Rsigma = 0.0035] | Rsigma = 0.0181] | Rsigma = 0.0253] |
| Data/restraints/ | 98/0/6 | 115/0/7 | 80/0/7 | 80/0/7 |
| parameters | | | | |
| Goodness-of-fit on F² | 1.319 | 1.310 | 1.182 | 1.256 |
| Final R indexes [I ≥ | R₁ = 0.0143, | R₁ = 0.0064, | R₁ = 0.0155, | R₁ = 0.0287, |
| 2σ(I)] | wR₂ = 0.0316 | wR₂ = 0.0156 | wR₂ = 0.0432 | wR₂ = 0.0826 |
| Final R indexes | R₁ = 0.0147, | R₁ = 0.0064, | R₁ = 0.0156, | R₁ = 0.0287, |
| [all data] | wR₂ = 0.0317 | wR₂ = 0.00156 | wR₂ = 0.0432 | wR₂ = 0.0826 |
| Largest diff. peak/ | 0.43/−0.97 | 0.32/−0.28 | 0.32/−0.28 | 0.81/−1.40 |
| hole/e Å⁻³ | | | | |

### Phase Identification and Elemental Analysis of High-Entropy Halide Perovskite Single Crystals

The resulting high-entropy five-element SnTeReIrPt, six-element SnTeReOsIrPt, five-element ZrSnTeHfPt and six-element ZrSnTeHfRePt single crystals are in the order of 30-100 μm in size and possess octahedral and cuboctahedral morphologies typical of a face-centered cubic (FCC) crystal structure (FIG. 1B). PXRD patterns of five-element SnTeReIrPt and six-element SnTeReOsIrPt HES single crystals (FIG. 2A) and of five-element ZrSnTeHfPt and six-element ZrSnTeHfRePt HES single crystals (FIG. 2D) show single-phase FCC crystal structures across all four compositions. Fine scans over the two prominent FCC reflections (111) and (220) highlight no peak splitting and are well fit with a single Lorentzian function as expected for diffraction peaks of a single-phase crystal system (FIGS. 2B-2C for SnTeReIrPt and SnTeReOsIrPt crystals and FIGS. 2E-2F for ZrSnTeHfPt and ZrSnTeHfRePt crystals). Furthermore, the lattice parameters of the four HES compositions are consistent with those of the constituent one-element single crystals (FIGS. 2A, 2D). Single-crystal X-ray diffraction (SCXRD) experiments performed on five-element SnTeReIrPt, six-element SnTeReOsIrPt, five-element ZrSnTeHfPt, and six-element ZrSnTeHfRePt single crystals confirm the cubic Fm3m space group with lattice parameters of 10.3035, 10.3110, 10.3868 and 10.3742 Å, respectively (Tables 1 and 2). Different octahedron types occupy crystallographically equivalent positions in the SCXRD-determined unit cell such that the resulting crystal structure is a FCC lattice of randomly alloyed M-sites (FIGS. 3A-3D). PXRD and SCXRD studies of all two-, three- and four-element single crystals also showed phase-pure FCC crystal structures with lattice parameters in line with the constituent one-element single crystals.

Extensive elemental analysis was conducted to confirm that each of the single-phase FCC crystal systems contain the five and six different M-site octahedral centers. EDX mapping (FIG. 4) and spectrum of a high-entropy six-element SnTeReOsIrPt single-crystal indicate the incorporation of all six elements homogeneously distributed within one single-crystal domain. EDX analysis of high-entropy five-element SnTeReIrPt, five-element ZrSnTeHfPt, and six-element ZrSnTeHfRePt single crystals similarly confirmed the presence and homogeneous distribution of the expected five, five and six M-site elements, respectively. The EDX spectra yield an approximate Cs:Cl molar ratio of 2:6 for all four HES compositions, with inductively coupled plasma atomic emission spectroscopy (ICP-AES) used for precise quantification of the molar ratio of the five and six different M-site metal centers. High-entropy five-element SnTeReIrPt, six-element SnTeReOsIrPt, five-element ZrSnTeHfPt, and six-element ZrSnTeHfRePt single crystals exhibited near-equimolar ratios among the constituent five and six M-site elements (Table 5). Furthermore, the ICP-AES results across all four HES compositions indicate an approximate Cs:overall M-site cation (that is, all five or six different M-site cations treated as a single M-site cation) molar ratio of 2:1. Combined EDX and ICP-AES analyses thus show that the stoichiometric values of the Cs cation, overall M-site cation and Cl anion in the formula unit are approximately two, one and six, respectively, with the precise experimentally determined stoichiometric compositions for the four HES crystal systems shown in Table 6. As a result, all four HES crystal structures is confirmed to possess five or six different M-site octahedral centers in near-equimolar ratios within an overall Cs₂MCl₆ vacancy-ordered double-perovskite framework. EDX and ICP-AES analyses of all two-, three- and four-element single crystals yielded compositional results similar to their high-entropy counterparts.

TABLE 5
ICP-AES molar concentrations of different M-site octahedral centers and
ICP-AES-determined element molar ratio of 5- or 6-element single crystals

| HES crystal | | | | | | | |
|---|---|---|---|---|---|---|---|
| system | ICP-AES Concentration (μM) | | | | | | ICP-AES Determined molar ratio |
| SnTeReIrPt | Sn | Te | Re | Ir | Pt | | Sn:Te:Re:Ir:Pt |
| | 37.34 ± | 41.13 ± | 37.97 ± | 32.36 ± | 39.47 ± | | 0.198:0.218:0.202:0.172:0.210 |
| | 0.615 | 0.368 | 0.150 | 0.099 | 0.554 | | |
| SnTeReOsIrPt | Sn | Te | Re | Ir | Pt | Sn | Sn:Te:Re:Os:Ir:Pt |
| | 50.46 ± | 44.01 ± | 40.22 ± | 39.86 ± | 32.78 ± | 35.32 ± | 0.208:0.181:0.166:0.164:0.135:0.146 |
| | 0.194 | 1.701 | 0.038 | 0.053 | 0.047 | 0.820 | |
| ZrSnTeHfPt | Zr | Sn | Te | Hf | Pt | | Zr:Sn:Te:Hf:Pt |
| | 90.52 ± | 49.95 ± | 70.65 ± | 54.07 ± | 74.94 ± | | 0.266:0.147:0.208:0.159:0.220 |
| | 0.395 | 0.227 | 0.792 | 1.272 | 0.174 | | |
| ZrSnTeHfRePt | Zr | Sn | Te | Hf | Re | Pt | Zr:Sn:Te:Hf:Re:Pt |
| | 51.66 ± | 27.29 ± | 39.84 ± | 28.20 ± | 30.91 ± | 40.37 ± | 0.237:0.125:0.183:0.129:0.142:0.185 |
| | 1.261 | 0.076 | 0.086 | 0.022 | 1.923 | 1.881 | |

TABLE 6
Experimentally-determined stoichiometric compositions
for the 5- element SnTeReIrPt, 6-element SnTeReOsIrPt,
5-element ZrSnTeHfPt, and 6-element ZrSnTeHfRePt single
crystals from combined EDX and ICP-AES analyses

| | Experimentally-Determined Stoichiometric |
|---|---|
| HES Crystal System | Composition |
| SnTeReIrPt | Cs₂Sn_{0.198}Te_{0.218}Re_{0.230}Ir_{0.117}Pt_{0.237}Cl₆ |
| SnTeReOsIrPt | Cs₂Sn_{0.208}Te_{0.181}Re_{0.166}Os_{0.186}Ir_{0.114}Pt_{0.146}Cl₆ |
| ZrSnTeHfPt | Cs₂Zr_{0.266}Sn_{0.147}Te_{0.208}Hf_{0.159}Pt_{0.220}Cl₆ |
| ZrSnTeHfRePt | Cs₂Zr_{0.237}Sn_{0.125}Te_{0.183}Hf_{0.129}Re_{0.142}Pt_{0.185}Cl₆ |

### Local Structures and Vibrational Behavior of High-Entropy Halide Perovskite Single Crystals

With the establishment of single-phase FCC Cs₂MCl₆ crystal systems containing five and six different M-site elements in near-equimolar ratios, a comprehensive structural understanding of these HES crystals was sought at various length scales, specifically across the atomic/molecular, unit cell and single-domain levels. Raman spectroscopy allows to explore the local structure of these new multi-element crystals. If no vibrational interactions are assumed between the various possible octahedral coordination environments28 within all crystals across both HES families, it is possible to fingerprint every phonon band to a particular octahedral unit within each single-crystal, and the crystal's vibrational structure becomes increasingly more complex with the incorporation of more octahedral molecules. With a greater understanding of the molecular structure from the Raman analysis, the unit cell level structure can be considered. The SCXRD results of the Cs₂{SnTeReOsIrPt}₁Cl₆ and Cs₂{ZrSnTeHfRePt}₁Cl₆ HES families discussed earlier can determine an average unit cell based solely on electron density. Given that many of the elements incorporated in the HES crystal systems possess similar electron density, in particular the neighboring Re, Os, Ir, and Pt elements, some degree of order could exist in the lattice that is not readily shown by electron density alone from conventional SCXRD.

A related technique that yields more highly resolved electron density, elemental distribution and potential short-range order information at the unit cell level is multiwavelength anomalous diffraction (MAD). MAD is a diffraction technique that determines the crystal structure from diffraction data collected at wavelengths corresponding to each heavy metal absorption edge of the HES compositions, thus providing more highly resolved electron density, elemental distribution, and potential short-range order information at the unit cell level. Each element has well-defined, characteristic core electron transitions based on its unique atomic energy level configuration. As a result, by probing at specific elemental absorbance resonances, the presence of a specific element within a HES crystal system and differentiate between heavy elements that are very close in atomic number can be confirmed, and the absolute configuration of metal centers and thus metal-ligand octahedral complexes (i.e., the [MCl₆]²⁻ octahedral complexes) in the HES crystal structures can be determined due to the inextricable coupling between X-ray scattering and X-ray absorption/excitation processes. This coupled behavior is referred to as anomalous scattering or anomalous dispersion, which modifies the atomic scattering factor to contain both magnitude and phase information in the form of real and imaginary components, respectively. The imaginary component of the anomalous scattering factor f″ is directly related to the atomic absorption coefficient for an element, and the real component of the anomalous scattering factor f′ is related to the imaginary component by the Kramers-Kronig (K-K) relation. As a result of these dependencies, the imaginary and real components of the anomalous scattering factor can be derived through X-ray fluorescence spectra that are collected simultaneous to the absorption edge-based diffraction experiments as a result of the absorption/excitation and relaxation processes occurring during these experiments.

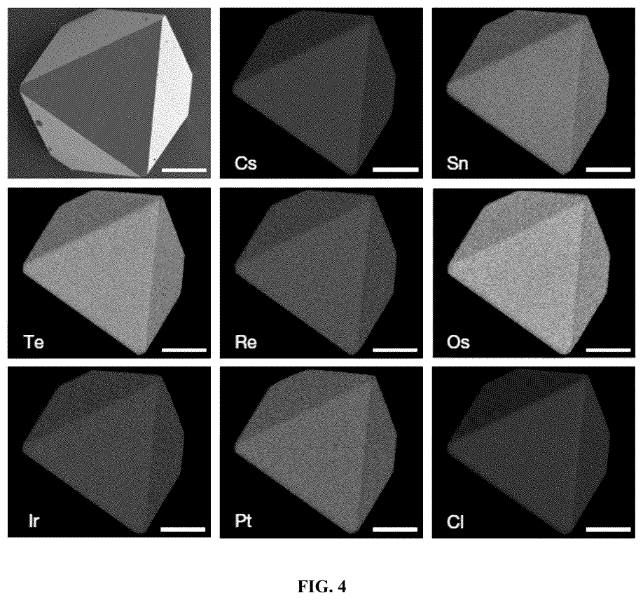

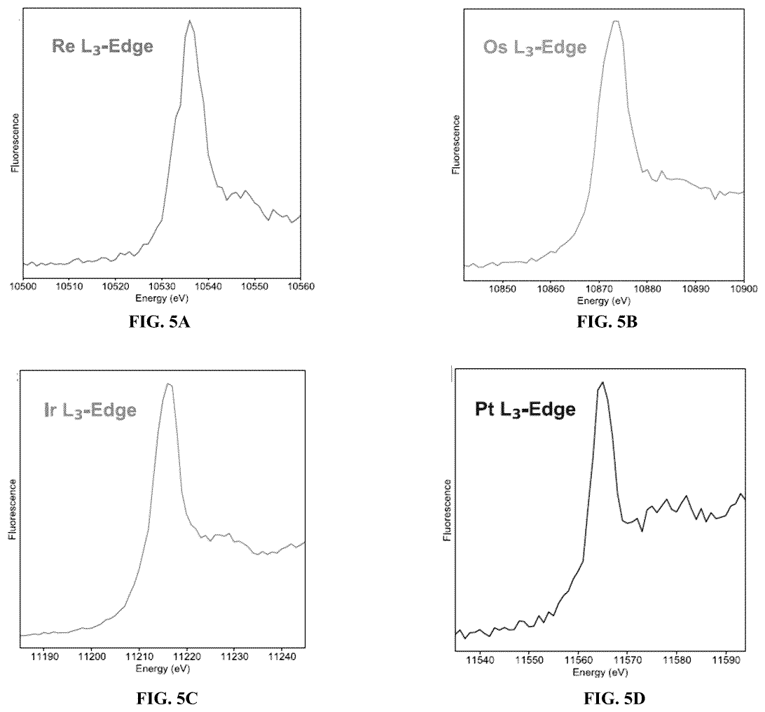

As a result of the excitation and relaxation processes occurring during these absorption edge-based diffraction experiments, X-ray fluorescence spectra were simultaneously collected across the Re, Os, Ir and Pt L₃ edges for a six-element SnTeReOsIrPt single-crystal (FIGS. 5A-5D). The imaginary component f″ and real component f′ of the resulting anomalous scattering factor can then be derived from these X-ray fluorescence spectra. Comparison of the Cromer-Liberman theoretically derived f″ and f′ and the X-ray fluorescence experimentally derived f″ and f′ near the Re, Os, Ir, and Pt L₃ edges in FIG. 6A shows that the energy values of the expected edges for both components align quite well between theory and experiment. This alignment further confirms the presence of Re, Os, Ir, and Pt within the unit cell of this six-element SnTeReOsIrPt single-crystal.

To visualize the absolute configuration of the six different [MCl₆]²⁻ octahedra in this unit cell, the MAD precession images generated from the 0kl plane collected near the L₃ edges of Re, Os, Ir and Pt were analyzed, all of which show a FCC lattice (FIGS. 6B-6E). If any of the four metals are arranged with any local order, the edges of the diffraction patterns would shift away from the overall FCC lattice. Therefore, the preservation of the FCC lattice observed at all edges in all four precession images indicates that all M-site elements in the six-element SnTeReOsIrPt single-crystal are randomly distributed in the unit cell and across the crystal structure (FIGS. 6F, 6G). From this more highly resolved structural information, the occupancy of the four probed metals on the M-site can be determined due to the relationship between site occupancy and f″ and f′. The occupancy of each metal is close to the expected value of one at its characteristic absorption edge (Table 7), and these occupancy values allow for the derivation of M-site metal ratios to ultimately provide elemental information complementary to the ICP-AES results of the six-element SnTeReOsIrPt single-crystal (Table 8). Similar X-ray absorption behavior and similar X-ray scattering behavior and overall structural insights were observed in the MAD analysis of a six-element ZrSnTeHfRePt single-crystal (Tables 9-10).

TABLE 7
Single-element occupancy of Re, Os, Ir, and Pt determined at the Re L₃-edge,
Os L₃-edge, Ir L₃-edge, and Pt L₃-edge in a 6-element SnTeReOsIrPt single crystal.
Because the Re L₃-edge, Os L₃-edge, Ir L₃-edge, and Pt L₃-edge are all very close in
energy, anomalous dispersion will still occur to some extent for all 4 elements under
scattering and absorption of all 4 wavelengths, causing the occupancy to be shifted
away from 1 for a metal that absorbs slightly away from its core transition (<1 if
the electron density is less than the electron density under true resonance and >1
if the electron density is greater than the electron density under true resonance).

| Element | Si(111) | Re L₃-edge | Os L₃-edge | Ir L₃-edge | Pt L₃-edge |
|---|---|---|---|---|---|
| Energy (eV) | 17012 | 10533 | 10869 | 11212 | 11562 |
| Wavelength (Å) | 0.7288 | 1.1771 | 1.1407 | 1.1058 | 1.0723 |

| Element | Occupancy | | | | |
|---|---|---|---|---|---|
| Sn | 1.2869 | 1.1467 | 1.1582 | 1.1438 | 1.1659 |
| Te | 1.2341 | 1.1064 | 1.1160 | 1.1026 | 1.1246 |
| Re | 0.8160 | 1.0219 | 0.8534 | 0.8275 | 0.8429 |
| Os | 0.8093 | 0.8472 | 1.0186 | 0.8304 | 0.8318 |
| Ir | 0.8030 | 0.8155 | 0.8410 | 0.9706 | 0.8347 |
| Pt | 0.7968 | 0.7910 | 0.8083 | 0.8155 | 0.9912 |

| Lattice Parameter | | | | | |
|---|---|---|---|---|---|
| a (Å) | 10.2918 | 10.3205 | 10.3163 | 10.3108 | 10.3078 |
| M—Cl (Å) | 2.3930 | 2.4050 | 2.4040 | 2.4050 | 2.4030 |

TABLE 8
Comparison of the ICP-AES-determined Sn:Te:Re:Os:Ir:Pt molar ratio
(from concentrations) and the MAD-determined Sn:Te:Re:Os:Ir:Pt
molar ratio (from occupancies at different wavelengths and electron
numbers) of a 6-element SnTeReOsIrPt single crystal

| | ICP-AES Determined Molar | MAD Determined Molar |
|---|---|---|
| Element | Ratio | Ratio |
| Sn | 0.262 | 0.4832 |
| Te | 0.177 | |
| Re | 0.147 | 0.1591 |
| Os | 0.176 | 0.0851 |
| Ir | 0.113 | 0.1828 |
| Pt | 0.124 | 0.0899 |

TABLE 9
Single-element occupancy of Zr, Hf, Re, and Pt determined at the Zr K-edge,
Hf L₃-edge, Re L₃-edge, and Pt L₃-edge in a 6-element ZrSnTeHfRePt single crystal.
Because the Hf L₃-edge, Re L₃-edge, and Pt L₃-edge are all very close in energy,
anomalous dispersion will still occur to some extent for those 3 elements under
scattering and absorption of those 3 wavelengths, causing the occupancy to be shifted
away from 1 for a metal that absorbs slightly away from its core transition (<1 if
the electron density is less than the electron density under true resonance and >1
if the electron density is greater than the electron density under true resonance).

| Element | Si(111) | Zr K-edge | Hf L₃-edge | Re L₃-edge | Pt L₃-edge |
|---|---|---|---|---|---|
| Energy (eV) | 17012 | 17995 | 9558 | 10533 | 11562 |
| Wavelength (Å) | 0.7288 | 0.6890 | 1.2972 | 1.1771 | 1.0723 |

| Element | Occupancy | | | | |
|---|---|---|---|---|---|
| Zr | 1.5610 | 1.8350 | 1.3589 | 1.3469 | 1.3997 |
| Sn | 1.1419 | 1.1174 | 1.0296 | 1.0200 | 1.0593 |
| Te | 1.0997 | 1.0728 | 0.9946 | 0.9850 | 1.0219 |
| Hf | 0.7598 | 0.7282 | 0.9691 | 0.7786 | 0.7646 |
| Re | 0.7363 | 0.7046 | 0.7454 | 0.9091 | 0.7646 |
| Pt | 0.7142 | 0.6840 | 0.6960 | 0.7037 | 0.9005 |

| Lattice Parameter | | | | | |
|---|---|---|---|---|---|
| a (Å) | 10.3523 | 10.3495 | 10.3809 | 10.3745 | 10.3000 |
| M—Cl (Å) | 2.4260 | 2.4250 | 2.4340 | 2.4350 | 2.4030 |

TABLE 10
Comparison of the ICP-AES-determined Zr:Sn:Te:Hf:Re:Pt molar ratio
(from concentrations) and the MAD-determined Zr:Sn:Te:Hf:Re:Pt
molar ratio (from occupancies at different wavelengths and electron
numbers) of a 6-element ZrSnTeHfRePt single crystal

| | ICP-AES Determined Molar | MAD Determined Molar |
|---|---|---|
| Element | Ratio | Ratio |
| Zr | 0.275 | 0.3091 |
| Sn | 0.207 | 0.2261 |
| Te | 0.158 | |
| Hf | 0.142 | 0.1784 |
| Re | 0.123 | 0.1956 |
| Pt | 0.095 | 0.0907 |

### Microstructure at the Single-Domain Level of High-Entropy Halide Perovskite Single Crystals

The final aspect of a comprehensive structural understanding of these HES compositions involves studying the potential microstructure at the single-domain level, which can be visualized using backscattered electron (BSE) imaging and electron backscattered diffraction (EBSD). HEAs are traditionally produced as faceted bulk materials with a complex microstructure of significant grain boundaries and varying grain orientations. As a result of this typical behavior in HEA materials (brought about in large part by their preparation procedures), it is crucial to confirm that our faceted HES compositions do not possess a microstructure of either phase-segregated constituent one-element grains or randomly oriented five- or six-element HES grains. The BSE images of a six-element ZrSnTeHfRePt system (FIG. 7A) show uniform phase contrast across all exposed crystal facets, in which phase contrast represents atomic number differences. Uniform atomic number contrast is also found in the BSE images of the complementary six-element SnTeReOsIrPt system (FIG. 7B). Therefore, a lack of variation in atomic number contrast indicates that there is no measurable phase separation of the six different M-site elements into micrograin structures, highlighting that each crystal does not form grains of phase-segregated constituent one-element compositions. EBSD analysis of a six-element SnTeReOsIrPt system further confirms the absence of phase-segregated one-element grains, but also confirms the absence of randomly oriented six-element grains within the single-domain. Scanning a region of approximately 45×50 μm2 across a flat, triangular facet (FIG. 7C) yielded an IPF of a single color (FIG. 7D), which corresponds to a single orientation of the FCC (111) close-packed plane (FIG. 7E). Therefore, a lack of IPF orientation variation shows that the HES crystal is not composed of randomly oriented six-element HES grains. The EBSD phase map reinforces this conclusion because the scan region possesses a single lattice parameter and thus a single crystal phase (FIG. 7F). Similar results were obtained from the IPF and phase map of the six-element ZrSnTeHfRePt system. The combined BSE imaging and EBSD analyzes establish that the five- and six-element HES systems are indeed single crystals of disordered constituent [MCl₆]²⁻ octahedra with no microstructure, which strongly corroborates previous MAD structural evidence.

### Optoelectronic Behavior of High-Entropy Halide Perovskite Single Crystals

From the varied structural and spectroscopic evidence presented here, the Cs₂{SnTeReOsIrPt}₁Cl₆ and Cs₂{ZrSnTeHfRePt}₁Cl₆ HES families represent solution syntheses of high-entropy metal halide perovskite single crystals containing near-equimolar ratios of disordered five and six different [MCl₆]²⁻ octahedra within a single-domain of the cubic Cs₂MCl₆ crystal framework. The multiple disordered octahedral units serve not only as the vibrational centers but also as the absorbing and emitting centers in these HES crystals, due to the M and Cl orbital character of the highest occupied molecular orbital (HOMO) and lowest unoccupied molecular orbital (LUMO). As a result of this material property, it is very likely that all five or six different isolated [MCl₆]²⁻ octahedra contribute to the absorption and emission behavior of the five- or six-element HES single crystals, respectively. The absorption spectra of these HES compositions reflect a superposition of electronic transitions from all five or six constituent octahedra within the crystal structure. In regard to the five-element ZrSnTeHfPt single crystals, the majority of the absorption spectrum (in the wavelength range 321-900 nm) has major contributions from the electronic transitions of the [TeCl₆]²⁻ and [PtCl₆]²⁻ octahedral molecules, as observed by the similar absorbance features between this HES composition and the constituent one-element Cs₂TeCl₆ and Cs₂PtCl₆ single crystals (FIG. 8B). The [TeCl₆]²⁻ and [PtCl₆]²⁻ octahedral molecules also contribute to the remainder of this absorption spectrum, with the dominant electronic contributions to the wavelength range 248.5-321.0 nm originating from the [ZrCl₆]²⁻, [TeCl₆]²⁻, [HfCl₆]²⁻ and [PtCl₆]²⁻ octahedral molecules and with the dominant electronic contributions to the wavelength range 225.0-248.5 nm originating from the [SnCl₆]²⁻ and [PtCl₆]²⁻ octahedral molecules. Nearly identical behavior, corresponding to the superposition of features from the electronic transitions of all constituent octahedra, was observed in the absorption spectra of six-element ZrSnTeHfRePt, five-element SnTeReIrPt and six-element SnTeReOsIrPt single crystals.

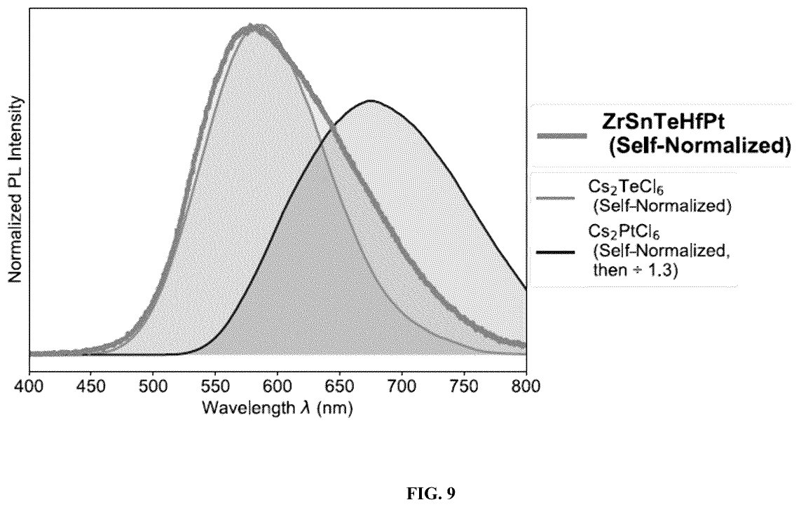

With the activation of all five or six different [MCl₆]²⁻ octahedral molecules in a particular crystal system following photoexcitation at a suitable wavelength, both radiative and non-radiative relaxation processes may be expected from all five or six different isolated octahedra, likely through confined excitons, leading to the emission spectrum of each HES composition as a superposition of spectral features from each [MCl₆]²⁻ octahedral molecule. However, this behavior is not observed in the emission spectrum for high-entropy five-element ZrSnTeHfPt single crystals. The five-element ZrSnTeHfPt HES composition exhibits gold emission centered at 580 nm (FIGS. 8A, 8C, 8D) with Commission Internationale de l'Eclairage (CIE) chromaticity coordinates of (0.49, 0.49) under 250 nm excitation (FIG. 8E). It is well established in the literature involving Cs₂MCl₆ that one-element Cs₂SnCl₆ single crystals do not emit; that one-element Cs₂ZrCl₆ and Cs₂HfCl₆ single crystals exhibit strong blue emission; that one-element Cs₂TeCl₆ single crystals exhibit yellow emission; and that Cs₂PtCl₆ single crystals exhibit red emission. Therefore, this gold emission (FIGS. 8C, 8D) results from the superposition of the confined exciton yellow emission from [TeCl₆]²⁻ octahedral molecules and the confined exciton red emission from [PtCl₆]²⁻ octahedral molecules. The blue shift in peak wavelength positions of the yellow- and red-emission spectral features in the five-element ZrSnTeHfPt single crystals as compared with the one-element Cs₂TeCl₆ and Cs₂PtCl₆ constituent crystals (FIG. 9) may be brought about by (1) changes in the type of excitons formed (from self-trapped excitons in one-element Cs₂MCl₆ single crystals to probably confined excitons in the HES single crystals) due to the inability to form a common free exciton band edge (a prerequisite for self-trapping) in a unit cell containing five disordered, isolated [MCl₆]²⁻ octahedra; (2) changes in local strain in the unit cell from five different disordered metal sites with different M-Cl bond lengths; and/or (3) changes in the excited-state potential energy surface as a result of the various M-Cl bond lengths and M-Cl molecular orbital characters in the unit cell.

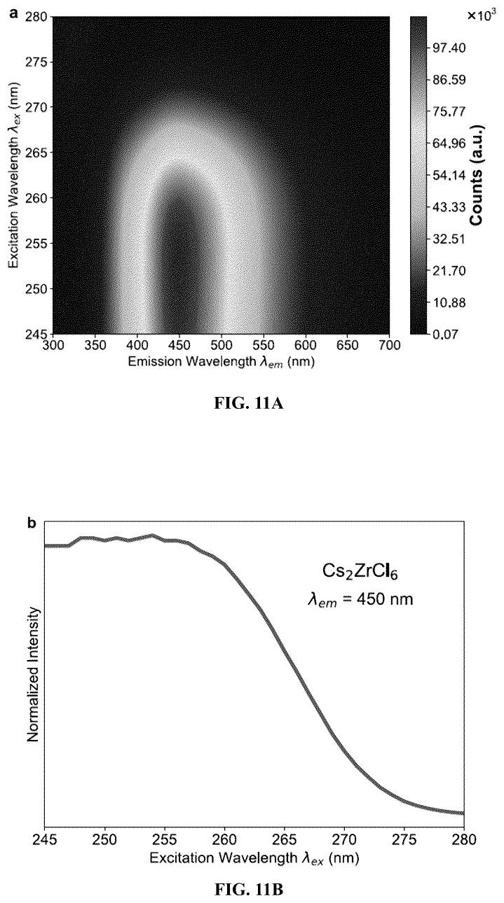

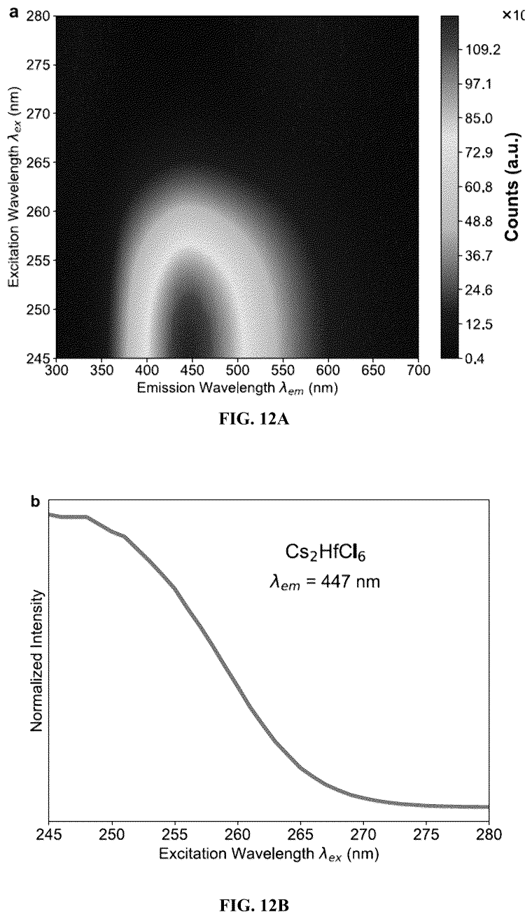

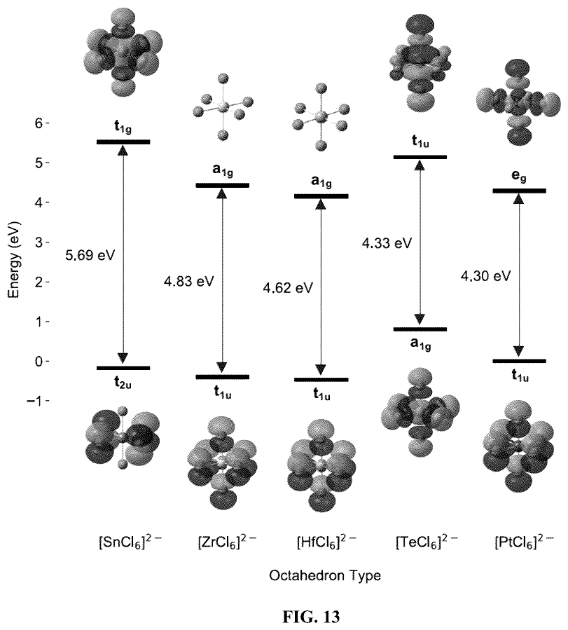

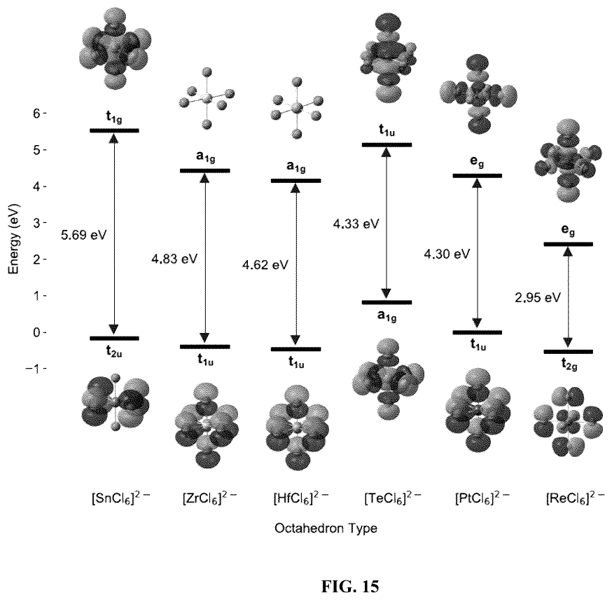

The complete absence of excitonic blue emission from [ZrCl₆]²⁻ and [HfCl₆]²⁻ octahedral molecules in the emission spectrum of this HES composition is potentially indicative of local heterogeneity in the excited-state potential energy surface (due to the disordered nature of the unit cell) affecting the oscillator strength of the parity-allowed ground-state to excited-state transition in [ZrCl₆]²⁻ and [HfCl₆]²⁻ octahedral molecules, coupled with (1) local heterogeneity in the excited-state potential energy surface affecting the efficiency of radiative decay in [ZrCl₆]²⁻ and [HfCl₆]²⁻ octahedral molecules and/or (2) energy transfer behavior from [ZrCl₆]²⁻ and [HfCl₆]²⁻ octahedral molecules to other octahedral centers in these crystals. Energy transfer among the five different octahedral centers in this solid-state framework is entirely feasible33,38 given that the length scale of separation between first-nearest-neighbor octahedra in this unit cell (3.88825-5.49878 Å) is well within those of Dexter and Forster resonance energy transfer mechanisms (below 10 Å for Dexter and below 10 nm for Forster resonance energy transfer). Indeed, energy transfer behavior is demonstrated in high-entropy five-element ZrSnTeHfPt single crystals through photoluminescence excitation (PLE) spectroscopy (FIGS. 10A-10B, 11A-11B, 12A-12B, 13), whereby the excited-state origin of the gold-emission band under 250 nm excitation is derived from [ZrCl₆]²⁻ and/or [HfCl₆]²⁻ octahedral molecules, thus confirming the process of energy transfer from the less strongly confined [ZrCl₆]²⁻ and/or [HfCl₆]²⁻ exciton states to the more strongly confined [TeCl₆]²⁻ and/or [PtCl₆]⁻ exciton states in this HES composition. The energy transfer process is also demonstrated in high-entropy six-element ZrSnTeHfRePt single crystals via PLE (FIGS. 14A-14B, 15), thereby implying that energy transfer behavior is likely present in all HES systems.

### SUMMARY

In summary, provided herein is room-temperature and low-temperature solution syntheses of two families of high-entropy metal halide perovskite semiconductor single crystals based on the cubic Cs₂MCl₆ vacancy-ordered double-perovskite structure from multi-element octahedral inks. Stabilization of various isolated [MCl₆]²⁻ octahedra within solution and their ability to be well-mixed in solution contributes to the formation of these HES single crystals under such low energy input. The achievement of any high-entropy material, especially in single-crystal form, at either room temperature or low temperature (80° C.) is unprecedented, and would help successful incorporation of future HES materials into products such as electronic device architectures or optoelectronic devices. The establishment of a single crystalline high-entropy halide perovskite semiconductor system facilitates intrinsic material property studies on the influence of the various isolated [MCl₆]²⁻ octahedra on the absorption behavior, electronic structure, energy transfer phenomena and emission properties for potential optoelectronic applications. The rational design of these metal halide perovskite HES single crystals via mild solution synthesis techniques has the potential for general application to other high-entropy alloy systems—particularly those with relatively low cohesive energies—in the discovery of new high-entropy magnetic or thermoelectric materials.

### Materials and Methods

Materials. CsCl (99.999% or greater, Sigma-Aldrich), ZrCl₄ (99.99%, Sigma-Aldrich), SnCl₄ (99.995%, Sigma-Aldrich), TeCl₄ (99.9%, Alfa Aesar), HfCl₄ (99.9%, Sigma-Aldrich), K₂ReCl₆ (99.99%, Sigma-Aldrich), K₂OsCl₆ (Os 38.7% min, Fisher Scientific), K₂IrCl₆ (99.99%, Sigma-Aldrich), PtCl₄ (99.99% or greater, Sigma-Aldrich) and 12 M HCl, 37% (Sigma-Aldrich) were used as received without further purification or modification.

General procedure for Cs₂ZrCl₆, Cs₂SnCl₆, Cs₂TeCl₆, Cs₂HfCl₆ and Cs₂PtCl₆ powders. Stoichiometric amounts of ZrCl₄, SnCl₄, TeCl₄, HfCl₄ or PtCl₄ precursor were dissolved in a vial containing 12 M HCl at room temperature (20° C.), and the stoichiometric amount of CsCl precursor was dissolved in a separate vial containing 12 M HCl at 20° C. The CsCl stock solution was then rapidly added to the ZrCl₄, SnCl₄, TeCl₄, HfCl₄ or PtCl₄ stock solution at 20° C. Cs₂ZrCl₆, Cs₂SnCl₆, Cs₂TeCl₆, Cs₂HfCl₆ or Cs₂PtCl₆ powders, respectively, were immediately precipitated out of solution at roughly 100% yield. Excess solution was removed, and powders were washed with ethanol, blown with N2 gas to dry and stored under vacuum in a benchtop desiccator.

General cation exchange procedure for Cs₂ReCl₆, Cs₂OsCl₆ and Cs₂IrCl₆ powders. Stoichiometric amounts of K₂ReCl₆, K₂OsCl₆ or K₂IrCl₆ powder were dissolved in an uncapped vial containing 12 M HCl at 100° C. and 1,000 rpm spin speed (using a magnetic stir bar). The stoichiometric amount of CsCl precursor was dissolved in a separate vial containing 12 M HCl at 20° C. K₂ReCl₆, K₂OsCl₆, or K₂IrCl₆ stock solutions were removed from the hotplate, the stir bar was removed and CsCl stock solution was then rapidly added to each stock solution. Cs₂ReCl₆, Cs₂OsCl₆ or Cs₂IrCl₆ powders, respectively, were immediately precipitated out of solution at around 100% yield. Excess solution was removed, and powders were washed with ethanol, blown with N2 gas to dry and stored under vacuum in a benchtop desiccator.

General single-crystal procedure for the Cs₂{SnTeReOsIrPt}₁Cl₆ HES family. Single crystals in the Cs₂{SnTeReOsIrPt}₁Cl₆ HES family were produced from an appropriate multi-element ink via a low-temperature (80° C.) reprecipitation synthesis (FIG. 1A). Stoichiometric amounts of Cs₂SnCl₆, Cs₂TeCl₆, Cs₂ReCl₆, Cs₂OsCl₆, Cs₂IrCl₆ and Cs₂PtCl₆ powders were dissolved in an uncapped vial containing 5 ml of 12 M HCl at 100° C. and 1,000 rpm spin speed (using a magnetic stir bar). The use of 12 M HCl as the solvent for these multi-element inks was a specific design choice, because an excess chloride environment promotes the formation of the six coordinated [MCl₆]²⁻ octahedral molecules in solution. Once all powders were dissolved, the stir bar was removed from the solution and the vial returned to the hot plate, which was turned down to 80° C. The vial remained uncapped and at 80° C. during the entire synthesis process. Synthesis was deemed complete when sufficient single crystals were seen at the bottom of the vial and a small amount of acid solution remained. Excess solution was removed, and single crystals were washed with ethanol, blown with N₂ gas to dry and stored in a vacuum desiccator. Among precipitates, 100% were single crystals of the desired single-phase composition. No other structures or products were formed during any of the syntheses or washing processes.

General single-crystal procedure for the Cs₂{ZrSnTeHfRePt}₁Cl₆ HES family. Single crystals in the Cs₂{ZrSnTeHfRePt}₁Cl₆ HES family were produced from an appropriate multi-element ink via a room-temperature (20° C.) reprecipitation synthesis (FIG. 1A). Very dilute stoichiometric amounts of Cs₂ZrCl₆, Cs₂SnCl₆, Cs₂TeCl₆, Cs₂HfCl₆, Cs₂ReCl₆ and Cs₂PtCl₆ powders were dissolved in a capped vial containing 20 ml of 12 M HCl at room temperature (20° C.) and 1,000 rpm spin speed (using a magnetic stir bar). Use of 12 M HCl as the solvent for these multi-element inks was a specific design choice, because an excess chloride environment promotes the formation of the six coordinated [MCl₆]²⁻ octahedral molecules in solution. Once all powders were dissolved, the solution was left in the capped vial at 20° C. until synthesis was complete. Synthesis was deemed complete when a sufficient amount of single crystals was seen at the bottom of the vial. Excess solution was removed, and single crystals were washed with ethanol, blown with N₂ gas to dry and stored in a vacuum desiccator. Among precipitates, 100% were single crystals of the desired single-phase composition. No other structures or products were formed during any of the syntheses or washing processes.

Optical microscopy. Optical microscopy was performed for visualization of single crystals using a Nikon SMZ-2T Trinocular stereo microscope with a ×6.3 objective in reflection mode (using an external light source) for the Cs₂{SnTeReOsIrPt}₁Cl₆ HES family, and with a Nikon Eclipse E600 polarizing microscope with a ×20 objective in transmission mode for the Cs₂{ZrSnTeHfRePt}₁Cl₆ HES family.

PXRD. Powder X-ray diffraction data were collected using a Bruker D8 laboratory diffractometer with a Cu Kα (λKα1=1.5406 Å, λKα2=1.54439 Å) radiation source under ambient conditions. Data were collected at 2θ=8-60° with a step size of 0.0181027° s⁻¹. Single crystals were ground into powder on glass for measurement. Data were analyzed using single Lorentzian functions in the Multipeak Fitting 2 procedure of IGOR Pro software.

SCXRD. Single-crystal X-ray diffraction data (SCXRD) was measured with a Rigaku XtaLAB P200 instrument equipped with a MicroMax-007 HF microfocus rotating anode and a Pilatus 200 K hybrid pixel array detector, using either monochromated Mo Kα radiation (λ=0.71073 Å) or monochromated Cu Kα radiation (λ=1.54184 Å). All crystal datasets were collected at room temperature (293 K). CrysAlisPro44 was used for data collection and data processing, including a multiscan absorption correction applied using the SCALE3 ABSPACK scaling algorithm within CrysAlisPro. Using Olex2 (Dolomanov et al. 2009 J. Appl. Crystallogr. 42, 339-341), structures were solved with the SHELXT46 structure solution program using intrinsic phasing and refined with the SHELXL refinement package using least-squares minimization. The metal site was separated into a disorder of all potentially incorporated metals (Zr, Sn, Te, Hf, Re, Ir, Os and Pt) by applying the EXYZ constraint. The occupancy of each incorporated metal was assigned to reflect the molar fraction of each element obtained from the results of ICP-AES experiments.

SEM, EDX and EBSD. A field-emission scanning electron microscope (Thermo Fisher Scientific, Scios 2 FIB/SEM) facilitated visualization of single-crystal morphologies via the secondary electron detector, and visualization of potential atomic number contrast across an entire crystal domain via the BSE detector. The EDX detector was used to determine elemental ratios and the EBSD detector to determine a single grain/single orientation in an entire crystal domain. Single crystals were placed and pressed onto double-sided conducting copper tape supported by an aluminium SEM pin stub. Samples used for standard secondary electron imaging and EDX elemental mapping were sputter-coated with gold before measurement, whereas those used for BSE imaging and EBSD grain and phase mapping were not.

ICP-AES. Inductively coupled plasma atomic emission spectroscopy measurements were collected using a Perkin Elmer ICP Optima 7000 DV Spectrometer.

ULF Raman spectroscopy. Raman spectra were measured using a confocal Raman microscope system (Horiba LabRAM HR Evolution) at the Stanford Nano Shared Facilities. Single crystals were dispersed on glass for measurement. Either a continuous-wave 632.8 or 785 nm laser was focused onto a crystal facet at a constant power density set by neutral-density filters. The Raman signal from the sample was collected using a microscope objective in a back-scattering geometry (×100, numerical aperture 0.6). For the 632.8 nm laser, ultra-low-frequency (ULF) Raman spectra were measured with an Andor Newton DU970P BVF EMCCD detector equipped with a diffraction grating of 1,800 grooves mm⁻¹ and an ULF filter package (10 cm⁻¹) to remove the Rayleigh scattering line from the signal. For the 785 nm laser, low-frequency Raman spectra were measured with the same detector, equipped with a diffraction grating of 600 grooves mm-1 and a notch filter (about 35-40 cm⁻¹) to remove the Rayleigh scattering line from the signal. Data were analyzed using the Multipeak Fitting 2 procedure in IGOR Pro software, implementing Lorentzian oscillators.

MAD. Multiwavelength anomalous diffraction determines the crystal structure of a single-crystal from diffraction data collected at wavelengths corresponding to the absorption edges of elements contained within that single-crystal, particularly heavy metal elements. MAD experiments were conducted at the Advanced Light Source Small Molecule Crystallography beamline 12.2.1. Diffraction data were collected with a Bruker D85 three-circle diffractometer and a PHOTON II CPAD detector running shutterless, both of which were coupled to a channel-cut Si(111) monochromator, facilitating tunability of the incident X-ray energy in the range 6-25 keV. A reference Si(111) measurement was collected at 17.012 keV. Anomalous diffraction experiments were conducted at the Re L₃ edge (10.5353 keV), Os L₃ edge (10.8709 keV), Ir L₃ edge (11.2152 keV) and Pt L₃ edge (11.5637 keV) for the Cs₂{SnTeReOsIrPt}₁Cl₆ single-crystal and at the Zr K edge (17.9976 keV), Hf L₃ edge (9.5607 keV), Re L₃ edge (10.5353 keV) and Pt L₃ edge (11.5637 keV) for the Cs₂{ZrSnTeHfRePt}₁Cl₆ single-crystal. X-ray fluorescence spectra were collected from those same absorption resonances using an Amptek XR-100SSD X-ray detector. All crystal datasets were collected at room temperature (298 K). Data were reduced using the SAINT program (v.8.38A) and analyzed for agreement using XPREP (part of the APEX3 software suite, v.2017.3-0). Data were corrected for absorption with SADABS50, selecting a 0.02 scale factor for restraint estimated standard deviation (ESD) and Strong Absorber for absorption type. Using the Olex2 software package, the structures were solved with SHELXT and refined using a full-matrix least squares on F₂ with SHELXL. In the CHOOCH software, raw X-ray fluorescence spectra were background subtracted, smoothed using spline fits and normalized to obtain the imaginary component of the anomalous scattering factor f″ near each L₃ absorption edge; the imaginary component was then used to calculate the real component of the anomalous scattering factor f′ using the Kramers-Kronig relation.

UV-visible near-infrared absorption spectroscopy. The absorption spectra of the samples were measured using a UV-visible near-infrared spectrophotometer (Shimadzu UV-2600). Data were collected in absorption mode over a wavelength range of 200-900 nm at a slow scanning rate. Single crystals were ground into a powder with BaSO₄ powder and measured using an integrating sphere attachment.

Photoluminescence spectroscopy. Photoluminescence measurements were collected with a home-built photoluminescence microscope system. Single crystals were crushed onto UV-grade quartz for measurement. A broadband deuterium lamp (Thorlabs SLS204 Stabilized Deuterium Lamp) was filtered down to a 250 nm excitation line using a bandpass filter (250 nm/10 nm). The 250 nm excitation line was focused obliquely onto the sample with a constant power density. The photoluminescence signal from the sample was collected using a microscope objective (×50) coupled to a longpass filter (cut-on wavelength, 325 nm) to remove the excitation line from the signal. Visible wavelength photoluminescence spectra were collected over a 5 s exposure time with a Si charge-coupled device detector cooled to −120° C. by liquid nitrogen and equipped with a diffraction grating of 150 grooves mm⁻¹.

Photoluminescence imaging. The gold-emission LED photograph was taken by combining five-element Cs₂{ZrSnTeHfPt}₁Cl₆ single crystals with a 250 nm LED. Five-element Cs₂{ZrSnTeHfPt}₁Cl₆ single crystals were crushed on glass and transferred to the LED by moving it across the crushed single crystals. The Cal Golden Bear emission photoluminescence image was taken by exciting five-element Cs₂{ZrSnTeHfPt}₁Cl₆ single crystals (which had been shaped into the Cal bear mascot) with a UV lamp (excitation wavelength, 254 nm). The bear mascot shape was achieved by generation of a shadow mask of that shape, placing the shadow mask on a non-emissive substrate, weighing out five-element Cs₂{ZrSnTeHfPt}₁Cl₆ single crystals onto the non-emission substrate through the shadow mask and very gently removing the shadow mask.

PLE. Photoluminescence excitation measurements were collected in the integrating sphere attachment of an Edinburgh FS5 spectrofluorometer. A layer of single crystals was placed in the polytetrafluoroethylene sample holder for measurement. Monochromatic light from a 150 W continuous-wave ozone-free xenon arc lamp created a wide range of excitation wavelengths that were focused onto the sample. Spectra were collected under 1 s dwell time with a UV-enhanced Si photodiode array equipped with a diffraction grating of 1,200 grooves mm¹.

Computational methods for molecular orbital wavefunctions and orbital energies of isolated octahedra. For each [MCl₆]²⁻ (M=Zr⁴⁺, Sn⁴⁺, Te⁴⁺, Hf⁴⁺, Re⁴⁺, Os⁴⁺, Ir⁴⁺, Pt⁴⁺) octahedral composition, density functional theory molecular orbital wavefunction and orbital energy calculations were performed for octahedra isolated in a vacuum using the Gaussian 16 W/GaussView 6.0 software package. Ground-state geometry optimization was completed for [ZrCl₆]²⁻, [SnCl₆]²⁻, [TeCl₆]²⁻, [HfCl₆]²⁻ and [PtCl₆]²⁻ octahedra such that calculations were performed at a ground-state-optimized Zr—Cl bond length of 2.450 Å (expected bond length 2.4671(10) Å from this work's Cs₂ZrCl₆ structure determination), ground-state-optimized Sn—Cl bond length of 2.423 Å (expected bond length of 2.4308(10) Å from this work's Cs₂SnCl₆ structure determination), ground-state-optimized Te—Cl bond length of 2.536 Å (expected bond length of 2.5387(9) Å from this work's Cs₂TeCl₆ structure determination), ground-state-optimized Hf—Cl bond length of 2.437 Å (expected bond length of 2.437(3) Å from this work's Cs₂HfCl₆ structure determination) and ground-state-optimized Pt—Cl bond length of 2.340 Å (expected bond length of 2.335(4) Å from this work's Cs₂PtCl₆ structure determination). Ground-state geometry optimization was not completed for [ReCl₆]²⁻, [OsCl₆]²⁻, and [IrCl₆]²⁻ octahedra: calculations were performed at a Re—Cl bond length of 2.740 Å greater than the ground-state-optimized bond length of 2.361 Å (expected bond length of 2.3667(17) Å from this work's Cs₂ReCl₆ structure determination), an Os—Cl bond length of 2.724 Å greater than the ground-state optimized bond length of 2.345 Å (expected bond length of 2.3450(9) Å from this work's Cs₂OsCl₆ structure determination) and a Ir—Cl bond length of 2.710 Å higher than the ground-state-optimized bond length of 2.331 Å (expected bond length of 2.331(2) Å from this work's Cs₂IrCl₆ structure determination). The use of greater bond lengths for these [ReCl₆]²⁻[OsCl₆]²⁻ and [IrCl₆]²⁻ octahedra is in accordance with the ligand field independence of the d-d electronic transition between the HOMO t2g and LUMO eg. As a result, the longer bond lengths for [ReCl₆]²⁻, [OsCl₆]²⁻ and [IrCl₆]²⁻ octahedra allow the calculations to better capture the d-d HOMO-LUMO transitions of a Re⁴⁺, Os⁴⁺ or Ir⁴⁺ center in the presence of an octahedral ligand field5²⁻. An unrestricted open-shell form of the HSE06 hybrid functional55 was used in combination with a SDD basis set incorporating Stuttgart-Dresden effective-core potentials56,57. All isolated molecules were left in a negatively charged state (²⁻) with resultant ground-state multiplicities of one for [ZrCl₆]²⁻, [SnCl₆]²⁻, [TeCl₆]²⁻, [HfCl₆]²⁻ and [PtCl₆]²⁻, two for [IrCl₆]²⁻, three for [OsCl₆]²⁻ and four for [ReCl₆]²⁻.

Materials, methods, and results provided in this Example are further described in Folgueras et al. 2023 Nature 621:282-288, https://doi.org/10.1038/s41586-023-06396-8. The crystallographic information files have been deposited in the Inorganic Crystal Structure Database under reference NOs. CSD 2216614-2216620, 2216624, 2216626, 2216627, and 2216636-2216643, and can be obtained via https://www.ccdc.cam.ac.uk/structures. The entire contents of the foregoing materials, including the supplementary information, are incorporated herein by reference.

The section headings used herein are for organizational purposes only and are not to be construed as limiting the subject matter described in any way.

What is claimed is:

1. A high-entropy material according to the formula Cs₂{M}Cl₆,
wherein {M} is a combination of at least five metal cations each occupying the M-site of the high-entropy material as a random alloy.

2. The high-entropy material of claim 1, wherein the at least five metal cations occupy the M-site in near-equimolar ratios.

3. The high-entropy material of claim 1, comprising a single phase single crystal.

4. The high-entropy material of claim 1, wherein the at least five metal cations are tetravalent metal cations selected from the group consisting of Zr⁴⁺, Sn⁴⁺, Te⁴⁺, Hf⁴⁺, Re⁴⁺, Os⁴⁺, Ir⁴⁺, and Pt⁴⁺.

5. The high-entropy material of claim 1, wherein the M comprises Sn⁴⁺, Te⁴⁺, Re⁴⁺, Ir⁴⁺, and Pt⁴⁺.

6. The high-entropy material of claim 3, according to the formula: Cs₂{SnTeReOsIrPt}₁Cl₆ or Cs₂{SnTeReOsIrPt}₁Cl₆.

7. The high-entropy of claim 6, according to the formula: Cs₂Sn_{0.198}Te_{0.218}Re_{0.230}Ir_{0.117}Pt_{0.237}Cl₆ or Cs₂Sn_{0.208}Te_{0.181}Re_{0.166}Os_{0.1861}Ir_{0.114}Pt_{0.146}Cl₆.

8. The high-entropy material of claim 1, wherein the M comprises Zr⁴⁺, Sn⁴⁺, Te⁴⁺, Hf⁴⁺, and Pt⁴⁺.

9. The high-entropy material of claim 8, according to the formula: Cs₂{ZrSnTeHfPt}₁Cl₆ or Cs₂{ZrSnTeHfRePt}₁Cl₆.

10. The high-entropy material of claim 9, according to the formula: Cs₂Zr_{0.266}Sn_{0.147}Te_{0.208}Hf_{0.159}Pt_{0.220}Cl₆ or Cs₂Zr_{0.237}Sn_{0.128}Te_{0.183}Hf_{0.129}Re_{0.142}Pt_{0.185}Cl₆.

11. A product comprising the high-entropy material of claim 1, wherein the product is a processable semiconductor ink, a semiconductor, an optoelectronic device, a light-emitting diode (LED), a display, an electronic device, or a computer chip.

12. A method of generating a high-entropy material, the method comprising:
contacting Cs⁺ molecules with at least five different [MCl₆]²⁻ molecules in a solvent, forming via a self-assembly process a high-entropy material according to the formula Cs₂{M}Cl₆,
wherein the at least five different [MCl₆]²⁻ molecules each comprise a different metal cation M, and
wherein {M} is a combination of the different metal cations each occupying the M-site of the high-entropy material as a random alloy,
wherein the method is conducted at a temperature of 100° C. or lower.

13. The method of claim 12, comprising
dissolving at least five different Cs₂MCl₆ powders in the solvent comprising chloride, wherein the at least five different Cs₂MCl₆ powders each comprise a different metal cation M.

14. The method of claim 12, wherein the solvent comprises 12 M HCl.

15. The method of claim 13, comprising
dissolving the at least five different Cs₂MCl₆ molecules in the solvent at 100° C. or a lower temperature, or at room temperature with stirring, forming a solution, and
letting the solution sit at 80° C. or a lower temperature, or at room temperature, forming the high-entropy material.

16. The method of claim 12, forming single phase, single crystals as the high-entropy material.

17. The method of claim 12, wherein the at least five different [MCl₆]²⁻ molecules are selected from the group consisting of [ZrCl₆]²⁻, [SnCl₆]²⁻, [TeCl₆]²⁻, [HfCl₆]²⁻, [ReCl₆]²⁻, [OsCl₆]²⁻, [IrCl₆]²⁻, and [PtCl₆]²⁻.

18. The method of claim 13, wherein the at least five different Cs₂MCl₆ powders comprise
(i) Cs₂SnCl₆, Cs₂TeCl₆, Cs₂ReCl₆, Cs₂IrCl₆, and Cs₂PtCl₆ powders,
(ii) Cs₂SnCl₆, Cs₂TeCl₆, Cs₂ReCl₆, Cs₂OsCl₆, Cs₂IrCl₆, and Cs₂PtCl₆ powders,
(iii) Cs₂ZrCl₆, Cs₂SnCl₆, Cs₂TeCl₆, Cs₂HfCl₆, and Cs₂PtCl₆ powders, or
(iv) Cs₂ZrCl₆, Cs₂SnCl₆, Cs₂TeCl₆, Cs₂HfCl₆, Cs₂ReCl₆ and Cs₂PtCl₆ powders.

19. The method of claim 12, forming the high-entropy material according to the formula Cs₂{SnTeReOsIrPt}₁Cl₆, Cs₂{SnTeReOsIrPt}₁Cl₆, Cs₂{ZrSnTeHfPt}₁Cl₆, or Cs₂{ZrSnTeHfRePt}₁Cl₆.

20. A high-entropy material generated by the method of claim 12.
